(19) United States
(12) Patent Application Publication
(10) Pub. No.: US 2026/0358441 A1
(43) Pub. Date: Nov. 12, 2026

(54) SYSTEMS AND METHODS FOR CORRECTING ORTHOGONALITY ERRORS OF A SENSOR DEVICE

(71) Applicant: Allegro MicroSystems, LLC, Manchester, NH (US)

(72) Inventors: Ahmed Hassan Fahmy, Andover, MA (US); Solène Bastien, Naves-Parmelan (FR); Khalid Chishti, Pepperell, MA (US)

(73) Assignee: Allegro MicroSystems, LLC, Manchester, NH (US)

(21) Appl. No.: 19/201,048

(22) Filed: May 7, 2025

(51) Int. Cl. G01R 33/00; G01R 33/06

(52) U.S. Cl. CPC G01R 33/0041; G01R 33/06

(57) ABSTRACT

Disclosed are example systems and methods for correcting orthogonality errors in a sensor device. In particular, described are example systems and methods that generate a virtual channel signal that is orthogonal to a channel signal in a magnetic field sensing device. The virtual channel signal may be generated, for example, by identifying amplitude and/or phase errors between two channel signals, and utilizing one or more correction factors corresponding to the identified amplitude and/or phase errors to generate the virtual channel signal. An angle signal may then be generated based on one of the channel signals and the virtual channel signal, and one or more output signals may be transmitted based on the angle signal.

### BACKGROUND

Sensor devices are often used to monitor parameters of a system. For example, sensor devices may be used to measure speed and/or direction of rotation of a rotation object, such as of a wheel. The speed and/or direction measurements may then be used, such as in the implementation of driver assistance applications.

As another example, sensor devices may be used to measure a position or angle of rotation of a rotation object, such as of a rotor of an electric motor. The measurement information may then be used to control the motor. For example, a controller may continuously receive a measured angle of rotation of the rotor, and may use this information to commutate the motor. That is, the measured angle information may be used by the controller to switch currents in motor windings, producing magnetic fields that cause the rotor to rotate. The controller can then control aspects of the motor, such as speed and torque, based on the measured angle information.

Numerous applications, spanning from industrial automation and robotics, to self-parking and power steering applications in automobiles, may require monitoring of a rotation speed, direction, angle, and/or position of a rotating object.

Some sensor devices monitor properties by detecting a magnetic field corresponding to a proximity or movement of a target using one or more magnetic field sensing elements. In magnetic field sensors including multiple magnetic field sensing elements, magnetic field signals from the sensing elements may be processed by separate processing channels to generate respective phase separated signals. One such magnetic field sensor is the Allegro MicroSystems, LLC ATS605LSG Dual Output Differential Speed and Direction Sensor integrated circuit (IC). Channel output, or speed signals, can be provided in the form of two-state binary signals having a frequency indicative of the speed of rotation of the target. Additional output signals can include additional information, such as a direction of a rotation of the target.

### SUMMARY

Disclosed are example systems and methods for correcting errors in a sensor device. In particular, described are example systems and methods that generate a virtual channel signal that is orthogonal in phase to a channel signal in a magnetic field sensing device. The virtual channel signal may be generated, for example, by identifying amplitude and/or phase errors between two channel signals, and utilizing one or more correction factors corresponding to the identified amplitude and/or phase errors to generate the virtual channel signal. An angle signal may then be generated based on one of the channel signals and the virtual channel signal, and one or more output signals may be transmitted based on the angle signal. Using systems and methods disclosed herein, a sensor device may automatically correct for errors, such as orthogonality errors caused by mechanical and/or electrical non-idealities in a system. The sensor device may automatically correct for orthogonality errors quickly, such as within one or two rotations of a rotating target. The sensor device may also automatically correct for orthogonality errors in real-time and continuously, such that the sensor device may compensate for new non-idealities that arise in a system over time.

In accordance with some embodiments, there is provided a sensor device. The sensor device comprises magnetic field sensing elements, each of the magnetic field sensing elements arranged to sense a magnetic field associated with a rotating target. The sensor device also comprises circuitry. The circuitry is configured to receive a first channel signal representative of the magnetic field as sensed by a first one or more of the magnetic field sensing elements, and receive a second channel signal representative of the magnetic field as sensed by a second one or more of the magnetic field sensing elements. The circuitry is also configured to identify an amplitude error and a phase error between the first channel signal and the second channel signal. The circuitry is further configured to determine a first correction factor based at least in part on the identified amplitude error and a second correction factor based at least in part on the identified phase error. The circuitry is also configured to generate a virtual channel signal based at least in part on the first correction factor and the second correction factor. The circuitry is still further configured to generate an angle signal based on the generated virtual channel signal and one of the first channel signal or the second channel signal.

In some embodiments, the generated virtual channel signal differs in phase from the first channel signal or the second channel signal by ninety degrees.

In further embodiments, the circuitry is further configured to correct for an offset of at least one of the first channel signal or the second channel signal.

In still further embodiments, the generated virtual channel signal is equal in amplitude to an amplitude of the first channel signal or an amplitude of the second channel signal.

In some embodiments, the sensor device further comprises a memory storing instructions, wherein the circuitry comprises a digital controller. The digital controller, when executing the instructions, is configured to identify the amplitude error and the phase error, determine first correction factor and the second correction factor, generate the virtual channel signal, and generate the angle signal.

In further embodiments, the circuitry further comprises a phase error extraction circuit for extracting the phase error between the first channel signal and the second channel signal. The circuitry still further comprises an amplitude error extraction circuit for extracting the amplitude error between the first channel signal and the second channel signal.

In still further embodiments, the phase error extraction circuit is configured to count a first time between a peak of the first channel signal and a peak of the second channel signal. The phase error extraction circuit is also configured to count a second time between two peaks of the first channel signal or the second channel signal. The phase error extraction circuit is further configured to determine the phase error based on the first time and the second time.

In some embodiments, the first correction factor is determined according to the formula

$$B = \frac{1}{A * cos ( φ )} ,$$

where B is the first correction factor, A is the amplitude error between the first channel signal and the second channel signal, and φ is the phase error between the first channel signal and the second channel signal.

In further embodiments, the second correction factor is determined according to the formula C=−tan(φ), where C is the second correction factor and φ is the phase error between the first channel signal and the second channel signal.

In still further embodiments, the first correction factor and the second correction factor are calculated using Pade's approximation.

In some embodiments, the first correction factor B is determined according to the formula

$$B = \frac{1}{A * cos ( φ )} ,$$

where A is the amplitude error between the first channel signal and the second channel signal, and φ is the phase error between the first channel signal and the second channel signal. The second correction factor C is determined according to the formula C=−tan(φ). The virtual channel signal is determined according to the formula Y_{corrected}=B*Y+C*Y, where Y_{corrected} is the virtual channel signal and Y is one of the first channel signal or the second channel signal.

In further embodiments, the circuitry is further configured to filter the first correction factor and the second correction factor. The circuitry is still further configured to generate the virtual channel signal based at least in part on the filtered first correction factor and the filtered second correction factor.

In still further embodiments, the circuitry is further configured to cause output signals to be transmitted, the output signals representing at least one of a speed of rotation of the rotating target or an angle of rotation of the rotating target.

In some embodiments, the magnetic field sensing elements comprise one of giant magnetoresistance (GMR) elements, Hall plate elements, or tunneling magnetoresistance (TMR) elements.

In further embodiments, the circuitry comprises a filtering circuit. The filtering circuit comprises a dynamic scaling factor circuit for scaling a bandwidth of the filtering circuit during operation of the sensor device. The filtering circuit also comprises a low pass filter circuit that filters the first correction factor and the second correction factor based at least in part on the scaled bandwidth and on a previously filtered first correction and second correction factor.

Furthermore, in accordance with some embodiments, there is provided a method. The method comprises receiving a first channel signal representative of a magnetic field as sensed by one or more magnetic field sensing elements, the magnetic field associated with a rotating target. The method also comprises receiving a second channel signal representative of the magnetic field as sensed by one or more second magnetic field sensing elements. The method further comprises identifying an amplitude error and a phase error between the first channel signal and the second channel signal. The method also comprises determining a first correction factor based at least in part on the identified amplitude error and a second correction factor based at least in part on the identified phase error. The method further comprises generating a virtual channel signal based at least in part on the first correction factor and the second correction factor. The method still further comprises generating an angle signal based on the generated virtual channel signal and one of the first channel signal or the second channel signal.

In some embodiments, the generated virtual channel signal differs in phase from the first channel signal or the second channel signal by ninety degrees and is equal in amplitude to an amplitude of the first channel signal or an amplitude of the second channel signal.

In further embodiments, the first channel signal and the second channel signal are arranged to be orthogonal to each other, and the first correction factor and the second correction factor are used to generate the virtual channel signal orthogonal to one of the first channels signal or the second channel signal to correct for orthogonality errors, the orthogonality errors caused by at least one of a mechanical or electrical non-ideality.

In still further embodiments, the method further comprises transmitting at least one of output event signals when the angle signal crosses predetermined threshold values or signals representing rotation angles.

In some embodiments, the first correction factor is determined according to the formula

$$B = \frac{1}{A * cos ( φ )} ,$$

where B is the first correction factor, A is the amplitude error between the first channel signal and the second channel signal, and φ is the phase error between the first channel signal and the second channel signal, where the amplitude error is a ration between an amplitude of the first channel signal and the second channel signal.

In further embodiments, the second correction factor is determined according to the formula C=−tan(φ), where C is the second correction factor and φ is the phase error between the first channel signal and the second channel signal.

In still further embodiments, the first correction factor B is determined according to the formula

$$B = \frac{1}{A * cos ( φ )} ,$$

where A is the amplitude error between the first channel signal and the second channel signal, and φ is the phase error between the first channel signal and the second channel signal. The second correction factor C is determined according to the formula C=−tan(φ). The virtual channel signal is determined according to the formula Y_{corrected}=B*Y+C*Y, where Y_{corrected} is the virtual channel signal and Y is one of the first channel signal or the second channel signal.

In some embodiments, the method further comprises filtering the first correction factor and the second correction factor. The method still further comprises generating the virtual channel signal based at least in part on the filtered first correction factor and the filtered second correction factor.

Before explaining example embodiments consistent with the present disclosure in detail, it is to be understood that the disclosure is not limited in its application to the details of constructions and to the arrangements set forth in the following description or illustrated in the drawings. The disclosure is capable of being practiced and carried out in various ways. Also, it is to be understood that the phraseology and terminology employed herein, as well as in the abstract, are for the purpose of description and should not be regarded as limiting.

It is to be understood that both the foregoing general description and the following detailed description are explanatory only and are not restrictive of the claimed subject matter.

### BRIEF DESCRIPTION OF THE DRAWINGS

The accompanying drawings are incorporated in and constitute part of this specification. The drawings, together with the description, illustrate and serve to explain the principles of various example embodiments of the disclosure.

FIG. 1 shows a block diagram of an example system including a target and a sensor device.

FIG. 2 shows a diagram of an example system, including a sensor device and a magnetic target.

FIG. 3A shows an example portion of a magnetic target and a plot showing example signals of channels of a sensor device sensing the magnetic target.

FIG. 3B shows an example portion of a magnetic target, a plot showing an example magnetic profile of the target as it rotates, a plot showing example output events in a high-resolution operation, and a plot showing example output events in a low-resolution operation.

FIG. 4A shows a plot of example output current pulses from a sensor device that convey information about a target.

FIG. 4B shows a plot of example sets of output current pulses from a sensor device that convey information about a target.

FIG. 5A shows a graph of example measured magnetic field signals.

FIG. 5B shows a graph of an example measured magnetic field signal and an example virtual magnetic field signal.

FIG. 5C shows a graph of an example angle signal.

FIG. 6 shows a diagram illustrating example errors between two channels of a sensor device.

FIG. 7 shows a diagram of an example system that compensates for orthogonality errors between two channels of a sensor device.

FIG. 8 shows a diagram of an example system that generates a virtual channel, consistent with embodiments of the present disclosure.

FIG. 9A shows a diagram of example parts of an example system for extracting an amplitude and phase error between two measured magnetic field channel signals, consistent with embodiments of the present disclosure.

FIG. 9B shows a diagram of additional example parts of the example system for extracting an amplitude and phase error between two measured magnetic field channel signals, consistent with embodiments of the present disclosure.

FIG. 10 shows a diagram of an example system for determining a phase error correction factor and an amplitude error correction factor based on the determined amplitude and phase errors, consistent with embodiments of the present disclosure.

FIG. 11 shows a diagram of an example system that filters a phase error correction factor and an amplitude error correction factor, consistent with embodiments of the present disclosure.

FIG. 12 shows a diagram of an example system that includes a phase and amplitude error extraction circuit and a filter circuit, consistent with embodiments of the present disclosure.

FIG. 13 shows a diagram of an example system that includes a circuit for generating a virtual channel based on offset-adjusted measured magnetic field channel signals and correction factors.

FIG. 14 shows a block diagram of an example system including a target and a sensor device, consistent with embodiments of the present disclosure.

FIG. 15A shows a graph of an example measured magnetic field signals.

FIG. 15B shows a graph of an example measured magnetic field signal and a virtual channel signal generated based on a phase error correction factor and an amplitude error correction factor.

FIG. 16 shows an example process for identifying an amplitude error and a phase error between two channel signals of a sensor device, determining correction factors, filtering the correction factors, generating a virtual channel based on the correction factors, generating an angle signal, and causing an output signal to be transmitted.

FIG. 17 shows an example computing environment.

FIG. 18 shows an example computing device.

The drawings are not necessarily to scale, or inclusive of all elements of a system, emphasis instead generally being placed upon illustrating the concepts, structures, and techniques sought to be protected herein.

### DETAILED DESCRIPTION

An object monitored by a sensor device is often referred to as a target. Accordingly, an object (e.g., ferromagnetic object, magnet) whose characteristics are sensed by the sensor device may be referred to as a “target” herein.

A target may be attached to a system to be monitored, such as a rotation object. For example, a target, such as a ring magnet, may be attached to an axle of a wheel or other type of rotation object, such that the target rotates as the rotation object rotates. That is, a target may be fixed to a rotation object, such that the target rotates with the rotation object at the same speed as the rotation object rotates. A sensor device may then monitor rotation of the target to obtain information about rotation of the rotation object.

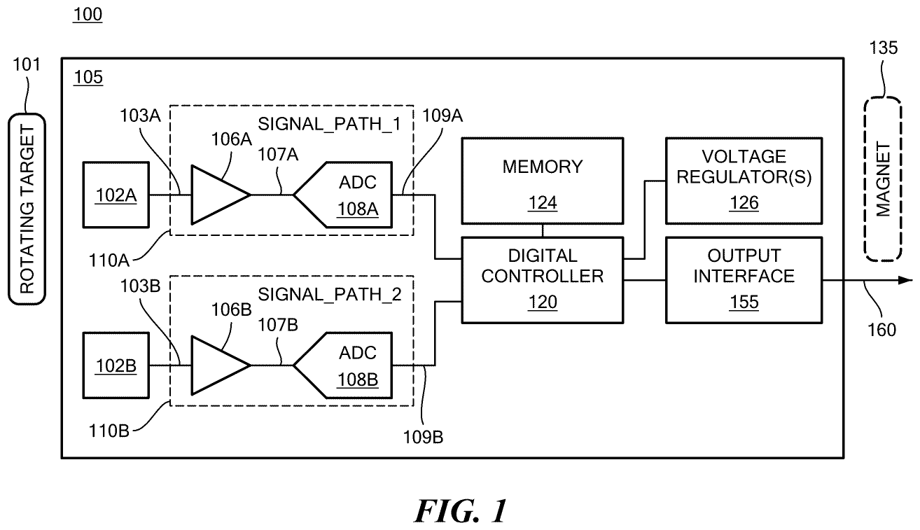

FIG. 1 is a block diagram of an example system 100. System 100 may be used to sense characteristics of a target and to output information representative of the characteristics of the target. For example, system 100 of FIG. 1 may include a target 101 and a sensor device 105 used to sense characteristics about target 101, such as a magnetic field generated by the target.

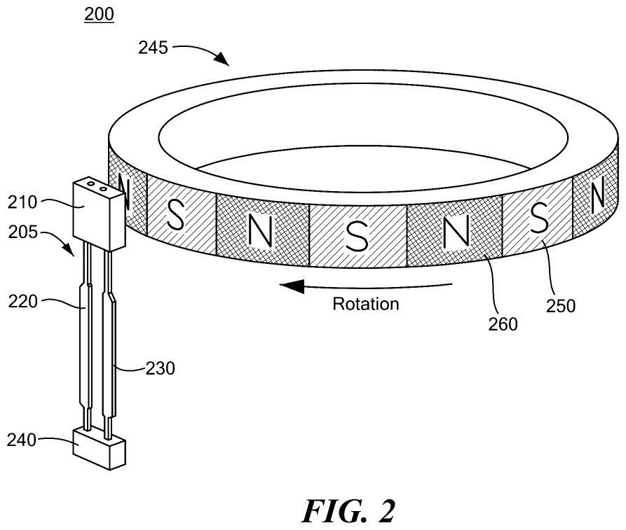

Target 101 may be, for example, a ring magnet with sections of alternating magnetic polarity (e.g., alternating north and south poles) (see, e.g., target 245 of FIGS. 2, 3A, 3B, 14), though the disclosure is not so limited. A person of ordinary skill in the art would recognize that many forms of magnet may be used, including, for example, disc magnets, bar magnets, horseshoe magnets, cylinder magnets, or any other form of a magnet.

A person of ordinary skill in the art would also recognize that a magnetic target may be a permanent magnet that stays magnetized once magnetized, a temporary magnet that behaves like a magnet only when near a magnetic field, an electromagnet that behaves like a magnet only when electricity is applied, or any other type of magnet. A person of ordinary skill in the art would recognize that a magnetic target may be made of any type of magnetic material, such as neodymium (e.g., neodymium-iron-boron (NdFeB)), samarium cobalt (e.g., SmCo), alnico (e.g., aluminum, nickel, cobalt), ceramic or ferrite (e.g., strontium carbonate, iron oxide), or any other type of magnetic material. A magnetic target may be diametrically magnetized and/or axially magnetized. A magnetic target may have any number of alternating north and south poles.

In some embodiments, target 101 may comprise a ferromagnetic material. For example, a target may be a ferromagnetic gear that may be rotated and that has gear teeth. A system (e.g., system 100) may also include a biasing magnet 135 that is positioned in proximity to a ferromagnetic target, resulting in fluctuations of a magnetic field proximate to the ferromagnetic target as the ferromagnetic target rotates. Use of a biasing magnet 135 in such a system may be referred to as a “back-bias” arrangement. Biasing magnet 135 is illustrated in FIG. 1 with a dotted line, as such a biasing magnet may not be necessary when target 101 is a magnet. Biasing magnet 135 may be any type of magnet previously discussed with respect to magnetic targets.

In some embodiments, target 101 may comprise one or more coils of wire, with current passing through the one or more coils of wire, such that a magnetic field is generated by the one or more coils of wire.

A sensor device (e.g., sensor device 105) may include one or more magnetic field sensing elements. For example, FIG. 1 illustrates sensor device 105 as comprising two magnetic field sensing elements, magnetic field sensing element 102A and magnetic field sensing element 102B. A magnetic field sensing element may be any type of element sensitive to a magnetic field. For example, a magnetic field sensing element may be a magnetoresistance element, a magnetotransistor element, a Hall-effect element, or a receiving coil element. For example, a magnetic field sensing element may be a magnetoresistance element, such as a giant magnetoresistance (GMR) element (e.g., a spin valve element), an Indium Antimonide (InSb) element, an anisotropic magnetoresistance (AMR) element, a tunneling magnetoresistance (TMR) element, or a magnetic tunnel junction (MTJ) element. A magnetic field sensing element may instead be a Hall-effect element, such as a planar Hall element, a vertical Hall element, or a circular vertical Hall (CVH) element. Alternatively, a magnetic field sensing element may be a receiving coil sensing element sensitive to a magnetic field generated by passing current through a coil of wire in the target.

A person of ordinary skill in the art would recognize that at least some of the above-described magnetic field sensing elements tend to have an axis of maximum sensitivity parallel to a substrate that supports the magnetic field sensing element, and others of the above-described magnetic field sensing elements tend to have an axis of maximum sensitivity perpendicular to a substrate that supports the magnetic field sensing element. In particular, planar Hall elements tend to have axes of sensitivity perpendicular to a substrate, while metal-based or metallic magnetoresistance elements (e.g., GMR, TMR, AMR) and vertical Hall elements tend to have axes of sensitivity parallel to a substrate.

Depending on the type of sensor device and application requirements, a magnetic field sensing element may be a device made of a type IV semiconductor material such as Silicon (Si) or Germanium (Ge), or of a type III-V semiconductor material such as Gallium-Arsenide (GaAs) or an Indium compound such as Indium-Antimonide (InSb). In some embodiments, multiple magnetic field sensing elements in a sensor device may be of the same type of magnetic field sensing element. For example, a sensor device (e.g., sensor device 105) may include two magnetic field sensing elements 102A and 102B, which may be of the same type. In some embodiments, there may be different types of magnetic field sensing elements that work together in a sensor device. For example, a sensor device (e.g., sensor device 105) may include two magnetic field sensing elements 102A and 102B, which may be of different types.

In some embodiments, magnetic field sensing elements (e.g., magnetic field sensing elements 102A, 102B) may output a voltage or current representative of (e.g., proportional to) a strength of a magnetic field. In some embodiments, magnetic field sensing elements may experience a change in resistance in response to a nearby magnetic field. For example, a magnetic field generated by a target 101 may cause a change in resistance in magnetic field sensing elements 102A, 102B. A voltage may then be detected across magnetic field sensing elements 102A, 102B by passing a current through the magnetic field sensing elements. The detected voltage may be proportional to the resistance of a magnetic field sensing element and may therefore be representative of the magnetic field that induced the resistance within the magnetic field sensing element.

A magnetic field sensing element may be a single element, or alternatively may include two or more magnetic field sensing elements. When a magnetic field sensing element includes two or more magnetic field sensing elements, those two or more magnetic field sensing elements may be arranged in one of various bridge configurations, such as a half bridge or full (Wheatstone) bridge.

In some embodiments, a sensor device (e.g., sensor device 105) may comprise a magnetic field sensing element 102A that comprises two magnetic field sensing elements (e.g., GMR elements) that are differentially paired, and a magnetic field sensing element 102B that comprises two magnetic field sensing elements (e.g., GMR elements) that are differentially paired. In some embodiments, a magnetic field sensing element 102A may comprise two magnetic field sensing elements that are differentially paired, and a magnetic field sensing element 102B may comprise two magnetic field sensing elements that are differentially paired, and one of the magnetic field sensing elements may be common to magnetic field sensing element 102A and magnetic field sensing element 102B.

For example, magnetic field sensing elements may be grouped in pairs, such that a difference between outputs of each of the pairs may be determined and output as a differential signal corresponding to the respective pair. Use of differentially-coupled magnetic field sensing elements in a sensor device may allow the sensor device to be immune to stray magnetic fields. For example, any magnetic field strength attributable to the environment, and not to a biasing magnet or to a target, may be sensed by each of the two magnetic field sensing elements in a differentially coupled pair. Because a magnetic field attributable to the environment will be approximately equally sensed at the two differentially paired magnetic field sensing elements (if they are in close proximity), any magnetic field strength measured by magnetic field sensing elements that is attributable to the environment will largely cancel out when a difference is taken between the measurements of the two differentially paired magnetic field sensing elements. That is, common-mode magnetic fields (i.e., common magnetic field strengths sensed by both magnetic field sensing elements in a differential pair) may be canceled out through use of differentially paired magnetic field sensing elements.

Signals (e.g., voltages) output from magnetic field sensing elements (e.g., magnetic field sensing elements 102A and 102B) may be processed and/or conditioned along signal paths, or “channels,” before being sent to a controller (e.g., digital controller 120). A channel for processing/conditioning a detected voltage may include, for example, an amplifier and an analog-to-digital converter (ADC). For example, FIG. 1 illustrates a channel (referred to herein as “left” channel) as including a signal path (e.g., SIGNAL_PATH_1 110A) that may include an amplifier 106A that receives a signal (e.g., signal 103A) from one or more magnetic field sensing elements 102A. An amplified version of signal 103A (e.g., signal 107A) may then be received by ADC 108A. A digital version of signal 107A (e.g., signal 109A) may then be received by a controller (e.g., digital controller 120). Similarly, FIG. 1 illustrates another channel (referred to herein as “right” channel) as including a signal path (e.g., SINGAL_PATH_2 110B) that may include an amplifier 106B that receives a signal (e.g., signal 103B) from one or more magnetic field sensing elements 102B. An amplified version of signal 103B (e.g., signal 107B) may then be received by ADC 108B. A digital version of signal 107B (e.g., signal 109B) may then be received by a controller (e.g., digital controller 120).

In some embodiments, amplifiers 106A, 106B may be differential amplifiers that each receive signals from two differentially paired magnetic field sensing elements, and output a difference between them as signal 107A, 107B, respectively. This type of arrangement may provide sensor device 105 with immunity to stray magnetic fields, as previously discussed.

Signals 109A, 109B may be generally sinusoidal in nature. Signals 109A, 109B may be referred to herein generally as measured magnetic field channel signals, which signals are indicative of a magnetic field affected by target 101. Thus, the sensor device may be considered to include a left processing channel (or simply left channel) including amplifier 106A and ADC 108A and outputting a left channel signal 109A and a right processing channel (or simply right channel) including amplifier 106B and ADC 108B and outputting a right channel signal 109B. Designations of “left” and “right” are arbitrary herein.

It will be appreciated that the term “channel” herein refers generally to processing circuitry (e.g., amplifier 106A, amplifier 106B, ADC 108A, ADC 108B) in a signal path and/or signals (e.g., signal 109A, signal 109B) output from a signal path and associated with one or more magnetic field sensing elements. While FIG. 1 illustrates an amplifier and an ADC as processing circuitry for each channel, such channels can include less, more, or different processing circuitry. For example, in some embodiments the channels may not include an ADC, and analog signals may be output as signals 109A, 109B and may be converted to digital signals within digital controller 120.

A sensor device may also include one or more controllers. The controller(s) may include digital and/or analog circuitry. For example, FIG. 1 illustrates sensor device 105 as including a digital controller 120. The controller may include any suitable type of processing circuitry, such as an application-specific integrated circuit (ASIC), digital logic circuitry, a coordinate rotation digital computer (CORDIC) processor, a special-purpose processor, synchronous digital logic, asynchronous digital logic, a general-purpose processor (e.g., microprocessor without interlocked pipelined stages (MIPS) processor, x86 processor), etc. The one or more controllers may also include a system clock. The system clock may timestamp when certain events are identified (e.g., timestamp with an elapsed amount of time measured by the clock), such that identified events and the times at which the events are identified may be stored in memory (e.g., memory 124). One of skill in the art will recognize that the system clock need not be internal to the one or more controllers, and may instead be an external component connected to the one or more controllers.

The sensor device may also include one or more memories. For example, FIG. 1 illustrates sensor device 105 as including a memory 124. The memory may include any suitable type of volatile and/or non-volatile memory. In some embodiments, the memory may be a non-transitory computer-readable medium. By way of example, memory 124 may include a random-access memory (RAM), a dynamic random-access memory (DRAM), an electrically-erasable programmable read-only memory (EEPROM), and/or any other suitable type of memory. The memory may store instructions, that when executed by the controller(s), cause the controller(s) to carry out certain determinations, steps, processes, and/or calculations.

The sensor device may include one or more voltage regulators. For example, FIG. 1 illustrates sensor device 105 as including voltage regulator(s) 126. Voltage regulator(s) may, for example, convert or regulate voltage to provide a stable power supply to the controller(s) (e.g., digital controller 120), magnetic field sensing element(s) (e.g., magnetic field sensing elements 102A, 102B), amplifier(s) (e.g., amplifier(s) 106A, 106B), ADCs (e.g., ADC(s) 108A, 108B), one or more memories (e.g., memory 124), output interface (e.g., output interface 155), and/or any other circuitry.

The sensor device may also include one or more interfaces for conveying information about the target. For example, FIG. 1 illustrates sensor device 105 as including one or more output interfaces 155. In some embodiments, an output interface 155 may modulate output current to output current pulses representing the information to be conveyed on a conductive interface 160. These current pulses may then be detected by another system (e.g., electronic control unit (ECU)), computing system 1730) connected to conductive interface 160. Alternatively, the sensor may convey information on a conductive interface using voltage pulses. Any known technique for outputting current pulses or voltage pulses may be used, and should be considered to be within the scope of the disclosure herein.

In some embodiments, a sensor device (e.g., sensor device 105) may convey information on other types of output interfaces 155. An output interface 155 may include one or more of a wired or wireless interface. By way of example, output interface 155 may include an Inter-Integrated Circuit (I²C) interface, a Controller Area Network (CAN) bus interface, a WiFi interface, an Ethernet interface, a Universal Serial Bus (USB) interface, a local area network (LAN) interface, a cellular (e.g., 5G) interface, and/or any other suitable type of interface.

In some embodiments a sensor device (e.g., sensor device 105) may convey information from an output interface 155 in digital or analog form.

In some embodiments, information may be conveyed by output interface 155 in accordance with a standardized protocol. In some embodiments, a sensor device (e.g., sensor device 105) may convey information in accordance with an AK protocol. In some embodiments, a sensor device may convey information as pulse-width modulated signals. Any suitable known protocol may be used to convey information out of the sensor device.

While symbols representing electronic circuits may be shown in FIG. 1 in the form of analog blocks or digital blocks, it is to be understood that analog blocks may be replaced by digital blocks that perform the same or similar functions and that digital blocks may be replaced by analog blocks that perform the same or similar functions.

It should also be understood that sensor device 105 may comprise additional circuitry. It should further be understood that digital controller 120 may comprise additional circuitry. As one example, comparators may be used in one or more of the sensor device and/or in one or more of the digital controllers. A comparator may be comprised of an analog comparator having a two state output signal indicative of an input signal being above or below a threshold level (or indicative of one input signal being above or below another input signal). A comparator may alternatively be comprised of a digital circuit having an output signal with at least two states indicative of an input signal being above or below a threshold level (or indicative of one input signal being above or below another input signal), respectively, or a digital value above or below a digital threshold value (or another digital value), respectively.

When the magnetic field sensing elements (e.g., magnetic field sensing element 102A, magnetic field sensing element 102B) are physically spaced apart from one another, a signal (e.g., signal 109A) output from the channel corresponding to one of the magnetic field sensing elements may differ in phase from a signal (e.g., signal 109B) output from the channel corresponding to the other of the magnetic field sensing elements. A phase difference between magnetic field signals output from magnetic field sensing elements may also be impacted by a number of pole pairs (or coils in a receiving coil implementation) of a target, a distance of the sensor device from a target, a spacing between magnetic field sensing elements of the sensor device, a mechanical misalignment of the sensor device to the target, mechanical imperfections of the target, and/or mechanical or electrical imperfections of components in the sensor device, as just some examples. In some embodiments, the phase separation between the signals may ideally be approximately ninety degrees (i.e., the signals may be approximately in a quadrature (or orthogonal) relationship). However, it will be appreciated that other phase relationships between the signals are possible.

Rotation speed of target 101 may be detected in accordance with the frequency of either of the phase separated channel signals 109A, 109B. In this way, channel signals 109A, 109B may be considered to contain redundant target speed information. It should be appreciated that a direction of rotation of target 101 may be determined from a relative phase or relative time difference (e.g., lag or lead) of a particular edge transition in signal 109A as compared with a particular corresponding edge transition in signal 109B. Therefore, a relative lag or a lead of edges of signals 109A, 109B may be used to identify a direction of rotation of target 101.

FIG. 2 shows an example system 200, which includes a target 245 that is a ring magnet with alternating north poles 260 and south poles 250, and a two-pin sensor device 205. Components of sensor device 105 shown in FIG. 1, for example, may be placed in an integrated circuit package, such as package 210 shown in FIG. 2. As one example, one of pins 220 and 230 may be a power supply (e.g., Vcc) terminal and the other of pins 220 and 230 may be a ground (GND) terminal, and information about target 245 sensed by sensor device 205 may be output on pin 220 or pin 230 via voltage and/or current pulses. 240 may be a structural piece (e.g., plastic piece) that holds pins 220 and 230 in position (e.g., for shipping or transport), and may be removed when sensor device 205 is mounted in a system. Sensor device 205 may measure magnetic field signals of target 245 as it rotates. Target 245 may be attached to a larger rotating object, such as a wheel of a vehicle. Monitoring rotation of target 245 by sensing the magnetic fields associated with target 245 as it rotates may allow sensor device 205, or a system (e.g., an ECU, a computing system 1730) downstream of sensor device that receives information from sensor device 205, to determine characteristics of the object (e.g., wheel) to which target 245 is attached, such as a rotation speed, rotation direction, and/or angle of rotation of the object.

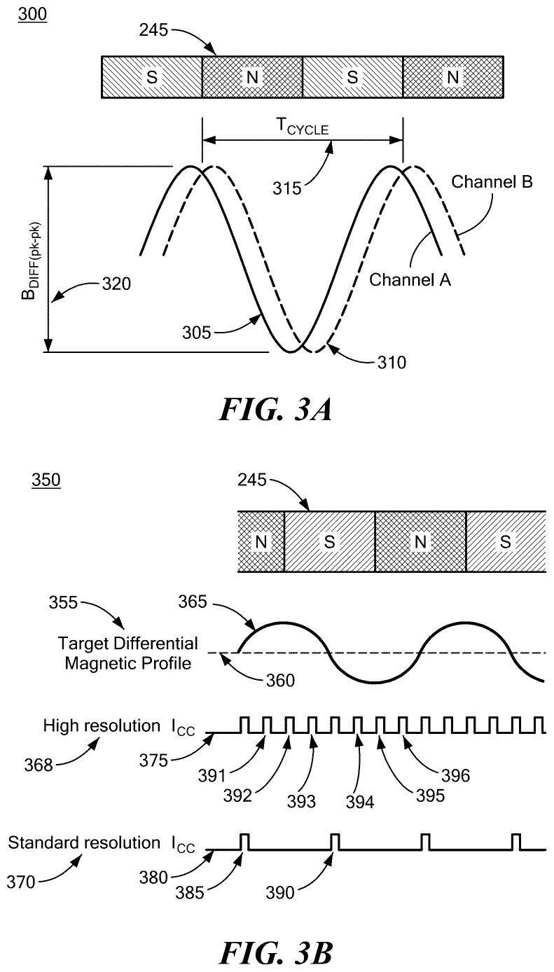

FIG. 3A is a diagram 300 showing example mechanical positions of target 245 in front of a sensor device (e.g., sensor device 105), and graphs of example channel signals representing a strength of the magnetic field sensed by the sensor device at the example mechanical positions of the target as the target rotates. For example, plot 305 (labeled as Channel A in FIG. 3A) may correspond to channel signal 109A or channel signal 109B of FIG. 1 as target 245 rotates. Plot 310 (labeled as Channel B in FIG. 3A) may correspond to the other channel signal of FIG. 1 (the other of channel signal 109A or channel signal 109B) as target 245 rotates. 315 represents the time of a cycle of the sinusoidal channel signal that is output as the target rotates. A period of the sinusoidal signal corresponds to the time it takes for target 245 to rotate such that one pole pair (a north pole and a south pole) passes by the face of the sensor device. 320 represents a difference between the highest and lowest magnetic field strengths sensed by the sensor device within a period of the sinusoidal signal.

FIG. 3B is a diagram 350 showing example mechanical positions of target 245 in front of a sensor device (e.g., sensor device 105). FIG. 3B also shows a graph 355 with a plot 365 of the differential magnetic flux sensed by an example sensor device when target 245 is rotated such that each of the shown mechanical position faces the sensor device. 360 corresponds to a magnetic field strength value (e.g., offset) around which the sinusoidal signal corresponding to the differential magnetic flux oscillates.

FIG. 3B also shows a graph 370 with a plot 380 of example output events that may be transmitted from a sensor device (e.g., sensor device 105) in a standard resolution mode of operation. For example, in a standard resolution mode of operation, two output events 385, 390 may be transmitted per period of the sinusoidal signal. A sensor device may be configured to detect when the sensed magnetic field strength of a channel signal (e.g., channel signal 109A, channel signal 109B) crosses a stored threshold value, and to transmit an output event when such a crossing occurs. In the example of FIG. 3B, this threshold value corresponds to the value 360 (e.g., offset value) of the magnetic field strength around which the sinusoidal signal oscillates. Each time the sinusoidal signal crosses this value in the positive or negative direction, an output event may be transmitted, such that there are two output events transmitted per period of the sinusoidal signal.

FIG. 3B also shows a graph 368 with a plot 375 of example output events that may be transmitted from a sensor device (e.g., sensor device 105) in a high resolution mode of operation. For example, in a high resolution mode of operation, in addition to the two output events (e.g., output events 385, 390) transmitted during a standard resolution mode of operation, additional output events may be transmitted that correspond to different angles of the sinusoidal signal. In the example shown in graph 368, six additional high resolution output events 391, 392, 393, 394, 395, 396 are shown, though the disclosure is not so limited.

Although FIG. 3B shows output of two output events per period of the sinusoidal signal in a standard resolution mode of operation, and eight output events (two standard resolution and six high resolution) output events per period of the sinusoidal signal in a high resolution mode of operation, the disclosure is not so limited. Any number of output events may be output per period of the sinusoidal signal, such as by setting different threshold values of the sensed magnetic field strength that trigger output events, or by generating an angle signal based on the channel signals and setting different threshold values of the angle signal for triggering output events, as will be further discussed herein.

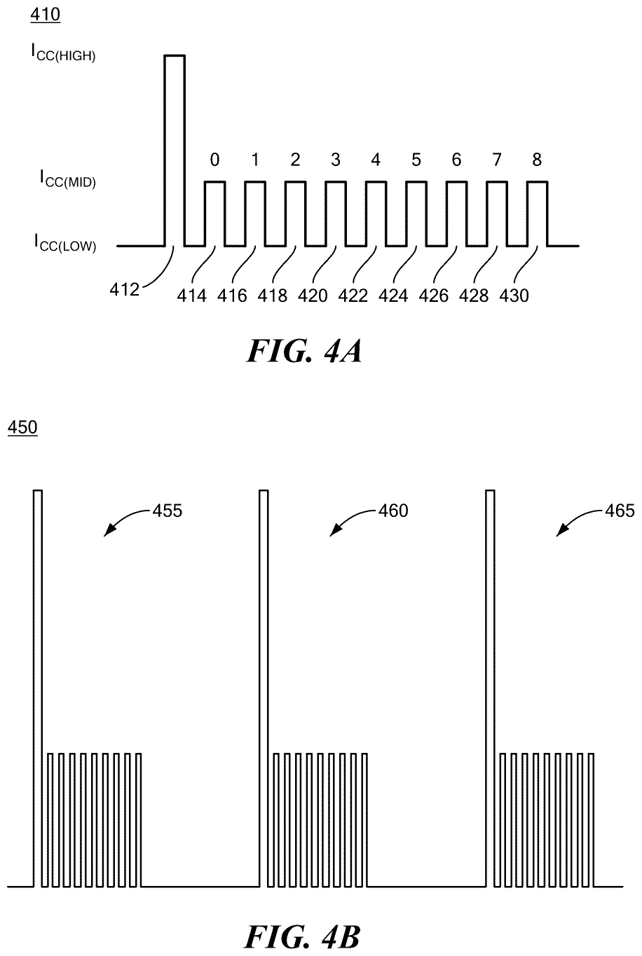

FIG. 4A shows a graph 410 with a plot of example output current pulses from a sensor device that convey information about a target. For example, the current pulses in the plot in graph 410 may correspond to one output event transmitted out of a sensor device, as discussed above with respect to FIG. 3B. FIG. 4A shows an example in accordance with AK protocol, where ten different current pulses may be output in one output event. In the example of FIG. 4A, pulse 412 may be output each time an output event is output, and may represent speed. A system receiving the transmitted output events may then determine a speed of rotation of the target (e.g., target 245) based on the frequency at which these pulses (pulses 412) are transmitted. Pulses 414, 416, 418, 420, 422, 424, 426, 428, and 430 may correspond to additional bits (e.g., bits 0-8) of an AK protocol output event (or word), and may convey additional information about the target. For example, each of these pulses may be at a logic high level (e.g., I_{CC(MID)}) or a logic low level (e.g., I_{CC(LOW)}, the value of which may represent different information about the target. The information represented by these pulses may include, for example, information about an air gap between the sensor device and the target, information about a status of the sensor device, information about whether the output event is a standard resolution output event or a high resolution output event, information identifying the particular threshold that triggered the output event, information identifying a direction of rotation, information regarding a parity bit, and/or other information regarding the target. In the example shown in FIG. 4A, three different current levels may be used to convey information in an output event. For example, a speed pulse may be transmitted with a pulse at a current level of I_{CC(HIGH)}, while the other pulses may be transmitted at a current level of I_{CC(MD)} (if at a logic high or “1” level) or at a current level of I_{CC(LOW)} (if at a logic low or “0” level).

FIG. 4B shows a graph 450 with a plot showing multiple groups of pulses, where each of the groups of pulses may correspond to an output event transmitted from a sensor device. For example, group of pulses 455 may correspond to a first output event, group of pulses 460 may correspond to a second output event, and group of pulses 465 may correspond to a third output event. Groups of pulses may be continually transmitted as a target rotates, and the frequency at which the groups of pulses are transmitted may change based on the speed of rotation of the target. Thus, a system receiving the pulses may determine a speed of rotation of the target by determining the frequency at which the speed pulses are transmitted within a given period of time.

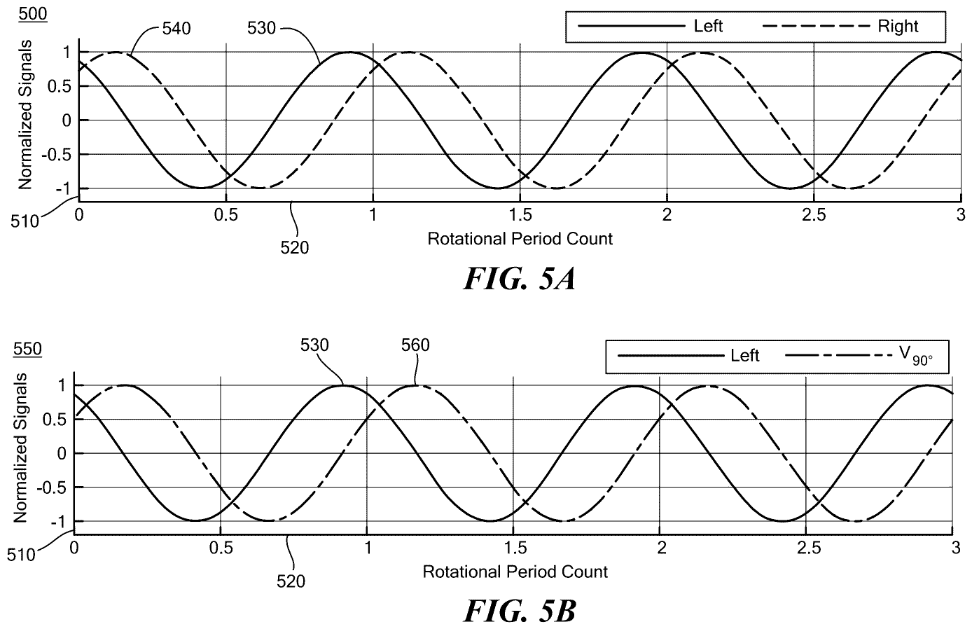

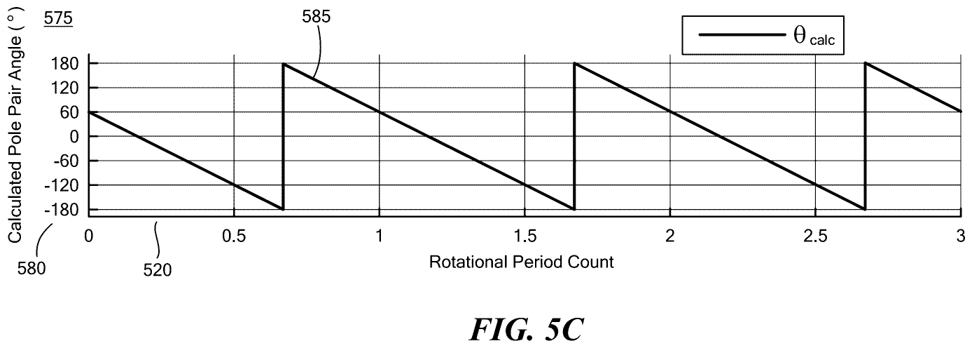

FIG. 5A shows a graph 500 of example measured magnetic field channel signals. Graph 500 includes a Y-axis 510 that represents a strength of magnetic field, and an X-axis 520 that represents a count of a rotational period. For example, for a ring magnet like target 245 of FIG. 2, a rotational period count of one may correspond to a rotation of the target such that a pole pair (i.e., one north and one south pole) passes the sensor device, while a rotational period count of 0.5 may correspond to a rotation of the target such that half of the pole pair passes the sensor device. A rotational period count of two may correspond to a rotation of the target such that two pole pairs pass the sensor device.

530 is an example plot of a measured magnetic field channel signal from one or more magnetic field sensing elements over a rotation of the target such that three pole pairs pass the sensor device (e.g., rotational period count of three). Example plot 530 was generated by simulating example measured magnetic field strengths that may be detected by example magnetic field sensing elements (e.g., magnetic field sensing element 102A) (e.g., left channel) as the target rotates such that a length of three pole pairs pass an example sensor device. In the example shown in FIG. 5A, plot 530 has a starting phase of 30 degrees (i.e., where a period of the sinusoidal signal represents 360 degrees).

540 is an example plot of a measured magnetic field channel signal from one or more magnetic field sensing elements over a rotation of the target such that three pole pairs pass the sensor device (e.g., rotational period count of three). Example plot 540 was generated by simulating example measured magnetic field strengths that may be detected by example magnetic field sensing elements (e.g., magnetic field sensing element 102B) (e.g., right channel) as the target rotates such that a length of three pole pairs passes an example sensor device.

It may be desirable to generate an angle signal that represents a rotation angle of the target based on the channel signals of the sensor device. Such rotation angle information may be useful in many applications, such as in power steering applications or applications where a motor needs to be commutated based on rotation angle information.

An angle signal may also be useful in applications where speed of rotation of a target needs to be determined. As previously discussed, speed sensor devices may output information (e.g., output events) about speed of rotation of a target when a sensed magnetic field strength of the target crosses certain threshold values. As also previously discussed, some speed sensor devices may provide for one or more high resolution modes of operation. For example, it may be desirable to output a greater number of output events to get more frequent information about a speed of rotation of the target. However, it may not be desirable to generate these greater number of output events by comparing an amplitude of the sinusoidal channel signal with threshold values. For example, as shown in FIG. 3B, the slope of the sinusoidal signal becomes very low at its peaks and troughs, which may lead to inaccuracy in determining when an amplitude of the sinusoidal signal crosses a threshold near these peaks or troughs (e.g., such as for triggering output events 392 and 395 in FIG. 3B). An angle signal (see, e.g., 585 of FIG. 5C) corresponding to the channel signals of a sensor device may have a constant slope throughout a rotational period of the target, as shown in FIG. 5C, and that constant slope may be sufficiently steep for accurately detecting when a threshold value has been crossed.

When channel signals of a sensor device are orthogonal to each other (i.e., separated in phase by ninety degrees), an angle of rotation of the target at any time may be determined. For example, an inverse tangent function (i.e., arctan function) may be applied to the channel signals at any given time to calculate an angle of rotation of the target at that time. As one example, the two-argument arctangent function a tan 2, commonly used in computing and mathematics, may be used to calculate a rotation angle of the target based on values (e.g., voltages) of channel signals at a given time. Various other techniques may be used to determine a measured rotation angle of the target instead of using an inverse tangent function, such as by using a lookup table, a polynomial fit, or a coordinate rotation digital computer (CORDIC) calculation. The calculations and/or processing required to determine the measured angle may be carried out by one or more controllers (e.g., digital controller 120) in the sensor device. That is, one or more controllers inside the sensor device may receive signals (e.g., voltages) from the two channels and determine a measured angle of rotation of the target based on the two channel signals using an inverse tangent function, lookup table, polynomial fit, or CORDIC calculation. Such a determination may be performed continuously, such that an angle signal such as that shown in FIG. 5C is generated as a target rotates.

As noted above, to determine an angle of rotation of the target, the channel signals in the sensor device may need to be orthogonal to each other. However, variations in a phase difference between the channels may occur due to, for example, differing numbers of pole pairs (or coils in a receiving coil implementation) of targets, varying distances between a sensor device and a target, varying spacings between magnetic field sensing elements of the sensor device, mechanical misalignments of the sensor device to the target, mechanical imperfections of the target, and/or mechanical or electrical imperfections of components in the sensor device, as just some examples. For example, in the graph shown in FIG. 5A, channel signal 530 (i.e., “Left” channel) and channel signal 540 (i.e., “Right” channel) are separated in phase by 75 degrees, and are thus 15 degrees off from being orthogonal to each other.

Some of this variation may be compensated for by carefully designing and testing components of the sensor device. Some of this variation may also be compensated for by calibrating (or trimming) the sensor device to a target in a particular application before operation.

FIG. 5B shows a graph 550 of an example measured magnetic field signal and an example virtual magnetic field signal. Graph 550 includes a Y-axis 510 that represents a strength of magnetic field, and an X-axis 520 that represents a count of a rotational period (as discussed above with respect to FIG. 5A).

530 is an example plot of a measured magnetic field signal from a magnetic field sensing element (e.g., “Left” channel signal) over a rotation of the target such that three pole pairs pass the sensor device, as discussed above with respect to FIG. 5A. 560 is an example plot of a virtual magnetic field signal that may be generated (e.g., by a controller, such as digital controller 120) to be phase-shifted from the measured magnetic field signal by ninety degrees. For example, a sensor device may be calibrated after being installed in a system to identify orthogonality errors, and a virtual magnetic field signal that is phase-shifted by ninety degrees from one of the measured magnetic field channel signals may be generated based on the identified orthogonality errors. As shown in FIG. 5B, virtual channel signal 560 is phase-shifted from channel signal 530 (e.g., “Left” channel signal) by ninety degrees.

The measured magnetic field channel signal and virtual channel signal may then be used to generate an angle signal, such as by applying an inverse tangent function, lookup table, polynomial fit, or CORDIC calculation to the amplitudes of the measured magnetic field channel signal and the virtual channel signal as discussed above. For example, an angle value may be determined at any given time by dividing a value of the measured magnetic field channel signal (e.g., channel signal 530 (“Left” channel)) at that time over a value of a ninety degree phase-shifted channel (e.g., channel signal 560 (virtual channel)) at that time (or vice versa) and then taking the arctangent of the result. This is given by the formula below, where M is a value of a first magnetic field channel signal (real or virtual) at a given time and P is a value of a second magnetic field channel signal (real or virtual) at that time, where the second magnetic field channel signal is phase-shifted from the first magnetic field channel signal by ninety degrees:

$$θ = arc tangent ( \frac{M}{P} ) \qquad Equation 1$$

where θ represents the calculated angle value at the given time. This equation may be used to record angle measurements over time.

FIG. 5C shows a graph 575 of example angle values determined by a sensor device based on the measured magnetic field channel signal (e.g., channel signal 530 (“Left” channel)) and the generated virtual channel (e.g., channel signal 560) over a rotation of a target. Graph 575 includes a Y-axis 580 representing angle value, and an X-axis 520 representing rotational period count of the target (as discussed above with respect to FIG. 5A).

Plot 585 is a plot of example angle values as the target rotates. As can be seen from graph 575, plot 585 of angle values may generally be a sawtooth function over the rotation of the target. As a result, the slope of the function is constant within a rotational period of a target and does not have very low slopes at peaks and troughs as in the case of sinusoidal signals (see, e.g., 530 or 540 of FIG. 5A). Any number of threshold level values may then be set in a sensor device (in hardware or in software) to trigger any number of output events based on these angle measurements. These thresholds may be set at regular intervals (e.g., 10 degrees, 20 degrees, 30 degrees) or irregular intervals. Thus, by calculating angle values over time, any number of output events may be triggered, including large numbers of output events, per pole pair based on the angle values, with high accuracy. Additional details regarding the generation and/or use of such angular data in triggering output events are disclosed in U.S. patent application Ser. No. 16/686,439, now U.S. Pat. No. 10,866,118, titled “High Resolution Magnetic Field Sensors,” filed Nov. 18, 2019, assigned to the Assignee of the subject application and incorporated by reference herein in its entirety.

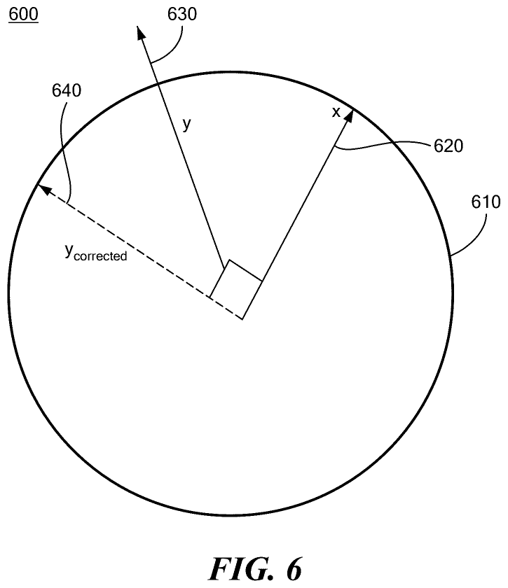

As discussed above, generating an angle signal within a sensor device that represents an angle of rotation of a target may be useful in rotation angle sensor applications and in speed sensor applications. However, due to orthogonality errors between channel signals in a sensor device, a virtual channel may need to be generated that compensates for the orthogonality errors between channels, such that the virtual channel is ninety degrees phase-shifted from one of the channel signals. FIG. 6 shows a diagram 600 that depicts the idea conceptually. A circle 610 in FIG. 6 represents 360 degrees, which corresponds to a rotational period of a target (e.g., a rotation of the target such that one pole pair passes by a sensor device). FIG. 6 also illustrates an example first channel signal 620 (represented in FIG. 6 by “x”) in a sensor device and an example second channel signal 630 (represented in FIG. 6 by “y”) in the sensor device that are not orthogonal to one another. As a result, it may be desired to generate a virtual channel signal 640 (represented in FIG. 6 by “y_{corrected}”) that is orthogonal to first channel signal 620 (“x”), so that an angle signal may be generated based on the orthogonal first channel signal and virtual channel signal.

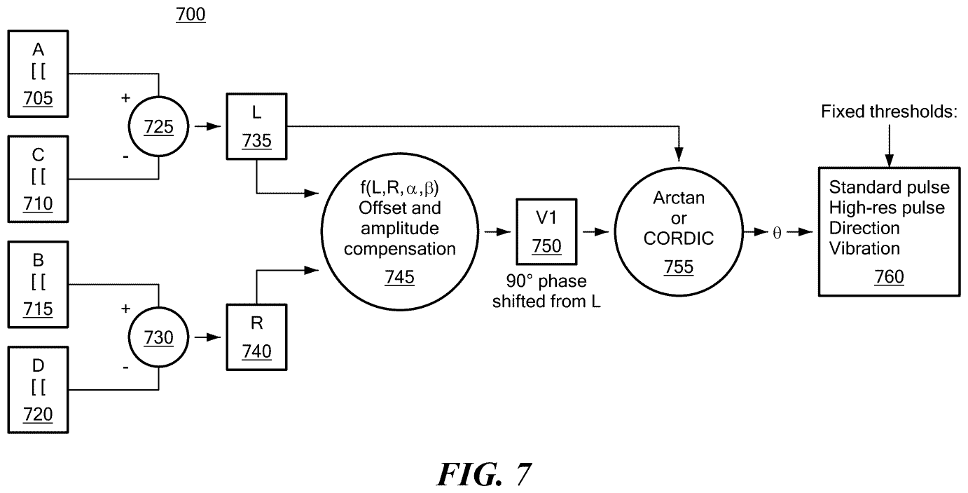

FIG. 7 shows a diagram of an example system 700 that may compensate for orthogonality errors between two channels of a sensor device. System 700 may be implemented in a sensor device, such as sensor device 105 or sensor device 205, though the disclosure is not so limited.

FIG. 7 illustrates system 700 as including four magnetic field sensing elements, magnetic field sensing element 705 (labeled as “A” in FIG. 7), magnetic field sensing element 710 (labeled as “C” in FIG. 7), magnetic field sensing element 715 (labeled as “B” in FIG. 7), and magnetic field sensing element 720 (labeled as “D” in FIG. 7). The magnetic field sensing elements may be any of the types of magnetic field sensing elements previously described with respect to FIGS. 1 and 2, and may be arranged in any of the ways discussed above with respect to FIGS. 1 and 2. The magnetic field sensing elements may be configured to sense a magnetic field generated by a rotating target, such as rotating target 101 or rotating target 245.

FIG. 7 illustrates the magnetic field sensing elements as being differentially paired. That is, magnetic field sensing element 705 (“A”) may be differentially paired with magnetic field sensing element 710 (“C”), such that one or more channel elements 725 (e.g., differential amplifier, ADC) may take a difference between the signals output from magnetic field sensing element 705 and magnetic field sensing element 710 and output the difference as a channel signal 735 (“Left” channel signal, labeled as “L” in FIG. 7). Similarly, magnetic field sensing element 715 (“B”) may be differentially paired with magnetic field sensing element 720 (“D”), such that one or more channel elements 730 (e.g., differential amplifier, ADC) may take a difference between the signals output from magnetic field sensing element 715 and magnetic field sensing element 720 and output the difference as a channel signal 740 (“Right” channel signal, labeled as “R” in FIG. 7). That is, channel element(s) 725 may correspond to the elements of SIGNAL_PATH_1 110A of sensor device 105, and channel element(s) 730 may correspond to the elements of SIGNAL_PATH_2 110B of sensor device 105, though the disclosure is not so limited. Similarly, Left channel signal 735 may correspond to signal 109A of sensor device 105, and Right channel signal 740 may correspond to signal 109B of sensor device 105, though the disclosure is not so limited.

Ideally, the output of the channel signals would be orthogonal to each other in phase, the channel signals would oscillate around the same value (or offset), and the peak-to-peak amplitude of the channel signals would be the same. If this were the case, the angle signal may be determined directly from the channel signals without using a virtual channel, using Equation 1 above for example or any of the other techniques previously discussed (e.g., arctan, a tan 2, lookup table, polynomial fit, CORDIC calculation). However, in practice in an application, the channel signals may not be perfectly orthogonal, the channel signals may not oscillate around the same offset value, and/or the peak-to-peak amplitudes of the channel signals may not be the same. Such variations may occur due to, for example, variations in number of pole pairs (or coils in a receiving coil implementation) of a target, variations in magnetic strength of target, variations in distance (e.g., air gap) of a sensor device from a target, a spacing between magnetic field sensing elements of the sensor device, a mechanical misalignment of the sensor device to the target, mechanical imperfections of the target, mechanical or electrical imperfections of components in the sensor device, or imperfect matching of components in the two channel paths of the sensor device (e.g., gain mismatch, such as in the analog front-end circuitry (e.g., amplifiers) of the sensor device), as just some examples.

To compensate for these non-idealities, the sensor device may be calibrated in a system once it has been installed, and element(s) 745, for example, may generate a virtual channel signal 750 (represented in FIG. 7 as “V1”) that is phase-shifted from one of the magnetic field channel signals (e.g., the Left channel “L”) by ninety degrees, that has the same offset (or value around which the sinusoidal output of the channel signal oscillates) as the magnetic field channel signal, and that has the same amplitude (e.g., peak-to-peak amplitude) as the magnetic field channel signal. An amplitude adjustment factor used to generate a virtual channel signal of the same amplitude as one of the measured magnetic field channel signals is represented by a in FIG. 7, while a phase adjustment factor used to generate a virtual channel signal that is ninety degrees phase-shifted from the measured channel signal is represented by β in FIG. 7. Any known technique in hardware and/or software for adjusting an offset, amplitude, and/or phase shift of a signal may be used to generate the virtual signal.

Once the virtual signal has been generated, an angle signal may be generated using element(s) 755. For example, hardware and/or software may be used to generate the virtual signal using Equation 1, by utilizing any of the techniques previously discussed (e.g., arctan, a tan 2, lookup table, polynomial fit, CORDIC), or using any other known technique for generating an angle signal or taking an arctangent from orthogonal signals. FIG. 7 illustrates element(s) 755 as performing an arctan or CORDIC function, though the disclosure is not so limited. Once the angle signal is generated, information regarding the target may be output based on the angle signal. For example, as previously discussed, in some systems it may be desired to output the angle signal, such that another system can determine an angle of rotation of the target. As also previously discussed, in some systems it may be desired to transmit output events, such that a speed and/or direction of rotation of the target may be determined. As shown in the example system of FIG. 7, a sensor device may compare an amplitude of the angle signal to set threshold values, and may trigger an output event to be sent each time the amplitude of the angle signal crosses one of the threshold values. As shown in FIG. 7, the output events may be output as part of a standard resolution mode of operation or as a high resolution mode of operation. The output events may be used by a receiving system (e.g., ECU, computing system 1730) to determine, for example, a speed of rotation of the target, a direction of rotation of the target, and/or a vibration of the target.

FIG. 7 and the associated discussion above demonstrates that it may be possible to correct offset, amplitude, and/or phase (orthogonality) errors between two channels, such as through careful design and testing of a sensor device and calibration of a sensor device after the sensor device has been installed in an application. However, such a solution may have disadvantages. For example, calibration of a sensor device in an application may be time-consuming, costly, and/or challenging to implement for a customer installing a sensor device in a system. Additionally, even when properly calibrated, new errors between two channels may develop over time due to, for example, temperature variations in an environment, failure or degradation of a component, wear and tear over time, changes in component characteristics over their lifetime (e.g., lifetime drift), and/or for other reasons. This may result in errors in the generated virtual channel and angle signal over time, such that the angle signal may no longer be relied upon by a system receiving information output from the sensor device.

Systems and methods disclosed herein can address these potential problems. For example, using systems and methods disclosed herein, a sensor device may automatically correct for errors, such as orthogonality errors between channels caused by mechanical and/or electrical non-idealities in a system. Using systems and methods disclosed herein, a sensor device may also automatically correct for offset and/or amplitude mismatch errors between channels, such as offset and/or amplitude mismatch errors between channels caused by mechanical and/or electrical non-idealities in a system. In some embodiments, the sensor device may automatically correct for orthogonality errors, offset errors, and/or amplitude errors quickly, such as within one or two rotations of a rotating target. As a result, using the systems and methods disclosed herein, it may no longer be necessary for a customer installing a sensor device in a system to calibrate the sensor device to adjust for orthogonality, offset, and/or amplitude errors, as the sensor device may quickly compensate for these errors automatically. Using the systems and methods disclosed herein, orthogonality, offset, and/or amplitude errors between channels may be automatically extracted and corrected in real-time as the sensor device operates, such that it may not be necessary for a customer to stop a system to recalibrate the sensor device. A sensor device utilizing the systems and methods disclosed herein may also automatically correct for orthogonality, offset, and/or amplitude errors in real-time and continuously, such that the sensor device may compensate for new non-idealities that arise in a system over time. Thus, using the systems and methods disclosed herein, a sensor device may automatically correct orthogonality, offset, and/or amplitude errors between channels (e.g., between measured magnetic field channel signals, between a virtual channel signal and a measured magnetic field channel signal) to help ensure the reliability of the generated angle signal and the ability to output information about a rotation angle, speed, and/or direction of rotation of a target with minimal or no error over the lifetime of the sensor device.

Before discussing the systems and methods disclosed herein in greater detail, some math is provided to demonstrate the concept mathematically. Assume there are two measured magnetic field channel signals having zero offset (e.g., having an offset of zero or an offset that has already been corrected to be zero) around which the two measured magnetic field channel signals oscillate. A first of the measured magnetic field channel signals (X) may correspond to signal 109A of FIG. 1, 530 of FIG. 5A, and/or 735 of FIG. 7, for example. A second of the measured magnetic field channel signals (Y) may correspond to signal 109B of FIG. 1, 540 of FIG. 5A, and/or 740 of FIG. 7, for example. Assume that the amplitudes of the two measured magnetic field channel signals are normalized to the amplitude of the first measured magnetic field channel signal (X), for simplicity. However, the amplitudes of the two measured magnetic field channel signals could instead be normalized to the amplitude of the second measured magnetic field channel signal (Y), or to some other value. The two measured magnetic field channel signals may then be represented by the equations below:

X=cos(θ) Equation 2:

Y=A*sin(θ+(φ) Equation 3:

where X is the first measured magnetic field channel signal, Y is the second measured magnetic field channel signal, θ is the angle of rotation of the target within a rotational period of the target, A is an amplitude error value representing a ratio of a peak amplitude of Y to a peak amplitude of X, and φ is an orthogonality error value representing a phase offset of Y from an orthogonal (i.e., ninety degree) phase shift from X. Note that X is represented by a cosine function here and Y is represented by a sine function here. As is known, a sine function is the same as a cosine function except that it is phase-shifted by ninety degrees. As a result, p corresponds to an amount of phase that Y is offset from a ninety degree phase shift from X.

The basic principle behind the example math here is to assume that the first measured magnetic field channel signal (X) is ideal and that the second measured magnetic field channel signal (Y) has to be corrected in comparison to the first measured magnetic field channel signal (X). The goal is to obtain orthogonal channel signals that have equal amplitude.

If the first measured magnetic field channel signal (X) is assumed to be ideal and the second measured magnetic field channel signal (Y) is to be corrected, then the first measured magnetic field channel signal (X) may be represented by Equation 2 above and the corrected second channel to be generated (i.e., the virtual channel to be generated) may be represented by the equation below:

Y_{corrected}=sin(θ) Equation 4:

where Y_{corrected} is the corrected second channel signal (or virtual channel signal).

As is known, Equation 3 may also be represented as the equation below:

Y≈A*sin(θ)*cos(φ)+A*cos(θ)*sin(φ) Equation 5:

For small values of orthogonality error (φ), cos (φ)≈1, and sin (φ)≈φ. Thus, for small values of orthogonality error (φ), Equation 5 may be reduced to the following equation:

Y≈A*sin(θ)+A*cos θ*φ Equation 6:

### Dividing Y by A, we get:

$$\frac{Y}{A} \approx sin ( θ ) + φ * cos ( θ ) \qquad Equation 7$$

The right side of Equation 7 can be rewritten in terms of the virtual channel (Y_{corrected}) and X using Equations 2 and 4 as follows:

sin(θ)+φ*cos(θ)=Y_{corrected}+φ*X Equation 8:

Solving for Y_{corrected} provides the following equations:

$${Y}_{corrected} = \frac{Y}{A} - φ * X \qquad Equation 9$$

$$or$$

$${Y}_{corrected} = B * Y + C * X \qquad Equation 10$$

$$where B = \frac{1}{A} and C = - φ ( in radians ) .$$

The angle signal may then be calculated according to the following equation:

$$Angle = arctan ( \frac{{Y}_{corrected}}{X} ) \qquad Equation 11$$

where Angle is the angle signal, representing the rotation angle of the target within a rotational period of the target at any given time.

However, orthogonality error (φ) may not always be small. Starting from Equations 2-4 and 10, Y_{corrected} can be written as the below equation:

A*B*sin(θ+φ)+C*cos(θ)=sin(θ) Equation 12:

which can be rewritten as the below equation:

A*B*cos(φ)*sin(θ)+A*B*sin(φ)*cos(θ)+C*cos(θ)=sin(θ). Equation 13:

Equating the coefficients of sin(θ) and cos(θ) on both sides of the equation results in

A*B*cos(φ)=1 Equation 14:

and

A*B*sin(φ)+C=0 Equation 15:

or

$$B = \frac{1}{A * cos ( φ )} \qquad Equation 16$$

$$and$$

$$C = \frac{- A * sin ( φ )}{A * cos ( φ )} = - tan ( φ ) . \qquad Equation 17$$

This means that the solution discussed above for small orthogonality errors still exists, except that the relation between the orthogonality error and the B and C coefficients is nonlinear. Equation 17 also implies a maximum theoretical range of correction that is between −π/2 radians to π/2 radians, or from −90° to 90°. Practically speaking, it may be reasonable to use coefficients B and C as correction factors to correct orthogonality errors within a range of −70° to 70° from a perfectly orthogonal signal. Outside of −70° to 70°, the C coefficient correction factor may become too large and too sensitive to use in practice to correct orthogonality errors.

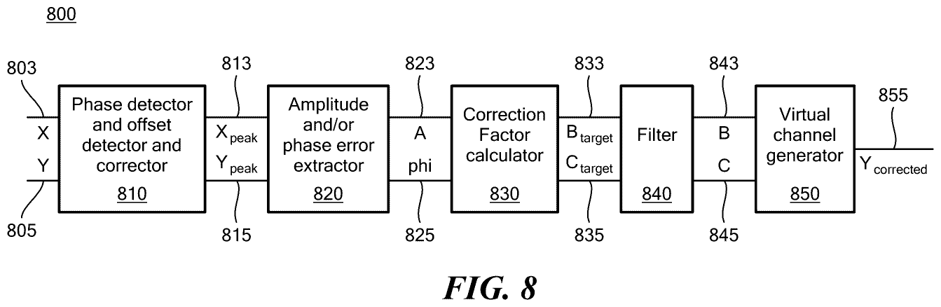

FIG. 8 shows a diagram of an example system 800 that generates a virtual channel, consistent with embodiments of the present disclosure. System 800 may be implemented within a sensor device, such as within sensor device 105, sensor device 205, or sensor device 1405. In some embodiments, system 800 may be implemented within a digital controller of a sensor device, such as digital controller 120 of sensor device 105, or within digital controller 1420 of sensor device 1405, as just some examples.

System 800 may include peak detector and offset detector and corrector 810. Peak detector and offset detector and corrector 810 may receive a first measured channel signal 803 (e.g., signal 109A of FIG. 1) (represented in FIG. 8 as “X”) and a second measured channel signal 805 (e.g., signal 109B of FIG. 1) (represented in FIG. 8 as “Y”). In some embodiments, peak detector and offset detector and corrector 810 may include peak detectors, for detecting a positive peak amplitude and/or negative peak amplitude for each of the measured channel signals. A person of ordinary skill in the art would recognize that there are many known ways to detect and store a value of a peak of a signal, any of which may be used to detect the peaks of the measured magnetic field channel signals here. In some embodiments, the peak detectors may comprise digital-to-analog converters (DACs) that track the positive peaks of the measured magnetic field signal (PDACs) and negative peaks of the measured magnetic field signal (NDACs), such is disclosed in U.S. Pat. No. 5,917,320, titled “Detection of Passing Magnetic Articles While Periodically Adapting Detection Threshold,” the disclosure of which is hereby incorporated by reference herein in its entirety. In some embodiments, the peak detectors may be implemented as described in U.S. Pat. No. 9,046,562, titled “Hysteresis Offset Cancellation for Magnetic Sensors,” the disclosure of which is hereby incorporated by reference herein in its entirety.

Peak detector and offset detector and corrector 810 may detect an offset of the measured magnetic field channel signals. Peak detector and offset detector and corrector 810 may be implemented in hardware (e.g., in digital and/or analog circuitry) or in software. The offset may correspond to a difference between a value around which the sinusoidal signal of a measured magnetic field channel signal oscillates and some other value. For example, circuitry of peak detector and offset detector and corrector 810 may detect an offset of one of the measured magnetic field channel signals with respect to the other measured magnetic field channel signal, or may detect an offset of each of the measured magnetic field channel signals from a predetermined value. A person of ordinary skill in the art would recognize that there are many known ways to detect and store an offset value of a signal, and to correct an offset value of a signal, any of which may be used to detect and correct the offset of a measured magnetic field channel signal here. In some embodiments, an offset value may be detected as and corrected as described in U.S. Pat. No. 9,046,562, titled “Hysteresis Offset Cancellation for Magnetic Sensors,” the disclosure of which is hereby incorporated by reference herein in its entirety.

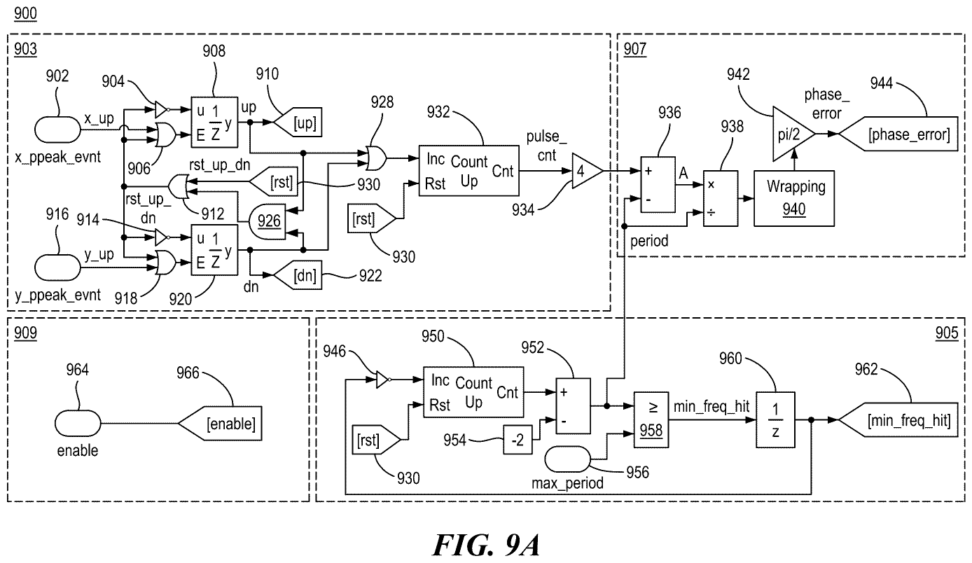

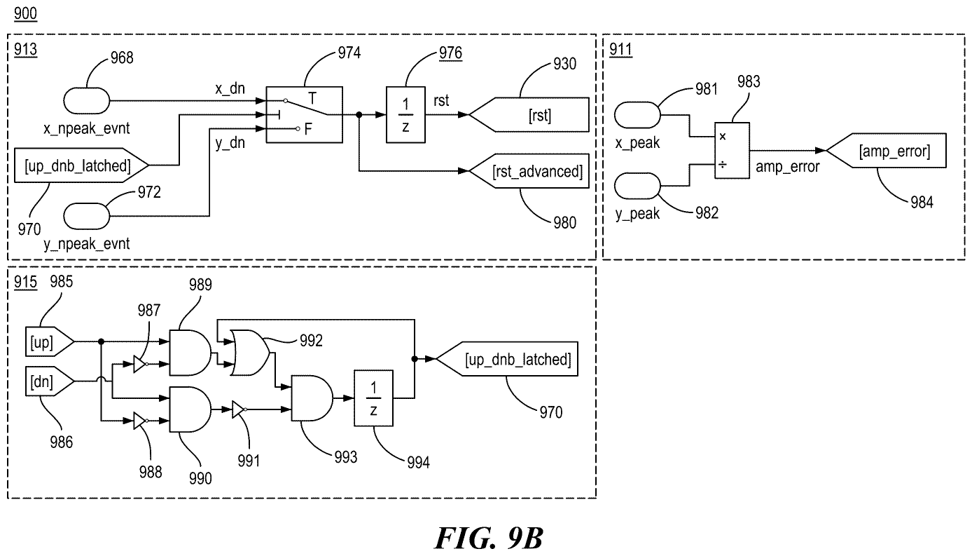

System 800 may also include amplitude and/or phase error extractor 820. Amplitude and/or phase error extractor 820 may be implemented in hardware (e.g., in digital and/or analog circuitry) or in software. Amplitude and/or phase error extractor 820 may receive one or more signals 813 (labeled in FIG. 8 as “Xₚₑₐₖ”) conveying information (e.g., value, occurrence) about the peaks of the first measured magnetic field channel signal from peak detector and offset detector and corrector 810, and one or more signals 815 (labeled in FIG. 8 as “Yₚₑₐₖ”) conveying information (e.g., value, occurrence) about the peaks of the second measured magnetic field channel signal from peak detector and offset detector and corrector 810. One example implementation of amplitude and/or phase error extractor 820 is shown in FIGS. 9A and 9B, and will be further discussed below. Amplitude and/or phase error extractor 820 may output a signal 823 representing a value “A” indicative of an amplitude error between one of the measured magnetic field channel signals (e.g., “X”) and the other measured magnetic field channel signal (e.g., “Y”), and a signal 825 representing a value “phi” indicative of an offset in phase from orthogonality (i.e., an offset in phase from a ninety degree offset) between one of the measured magnetic field channel signals (e.g., “X”) and the other measured magnetic field channel signal (e.g., “Y”).

System 800 may also include correction factor calculator 830. Correction factor calculator 830 may be implemented in hardware (e.g., in digital and/or analog circuitry) or in software. Correction factor calculator 830 may be configured to receive the values “A” and “phi” from amplitude and/or phase error extractor 820. In some embodiments, correction factor calculator 830 may be configured to calculate and output signals 833, 835 representing target values for correction factors “B” and “C,” respectively, such as correction factor “B” and “C” of Equations 16 and 17, or of Equation 10, above. In some embodiments, corrector factor calculator 830 may determine “B” and “C” of Equations 16 and 17 by approximating “B” and “C” using Pade's approximation. An equation for Pade's approximation for a function f(x) is given below:

$${R}_{m , n} ( x ) \approx \frac{{\sum }_{j = 0}^{m} {a}_{j} {x}^{j}}{1 + {\sum }_{k = 1}^{n} {b}_{k} {x}^{k}} = \frac{{a}_{0} + {a}_{1} x + {a}_{2} {x}^{2} + … + {a}_{m} {x}^{m}}{1 + {b}_{1} x + {b}_{2} {x}^{2} + … + {b}_{n} {x}^{n}} \qquad Equation 18$$

where m is an integer greater than or equal to 0, n is an integer greater than or equal to 1, and R_{m,n}(x) is the Pade's approximation of the function f(x). m and n represent the order of the approximation, and may be optimized mathematically based on a desired accuracy and allowed error tolerance between values of the approximation and values of the function. A person of ordinary skill in the art would recognize that there are known techniques using software and/or digital logic circuitry to calculate Pade's approximation, and any of these known techniques should be considered to be within the scope of the disclosure herein. In some embodiments, the order (e.g., m, n) and coefficients of the Pade's approximation may be predetermined and stored (e.g., in memory 124) or otherwise incorporated into the implementation of a digital controller (e.g., digital controller 120, digital controller 1420). In other embodiments, the order (e.g., m, n) and coefficients of the Pade's approximation may be determined by a digital controller (e.g., digital controller 120, digital controller 1420) as the sensor device operates.

In some embodiments, correction factor calculator circuitry 830 may instead determine “B” and “C” of Equations 16 and 17 by approximating “B” and “C” using Taylor series expansion. A person of ordinary skill in the art would recognize that there are known techniques using software and/or digital logic circuitry to approximate a value by calculating a Taylor series expansion, and any of these known techniques should be considered to be within the scope of the disclosure herein.

Of course, there are other known techniques for approximating the value of a secant function (Equation 16) and a tangent function (Equation 17), and any of these known techniques may be used to approximate these values.

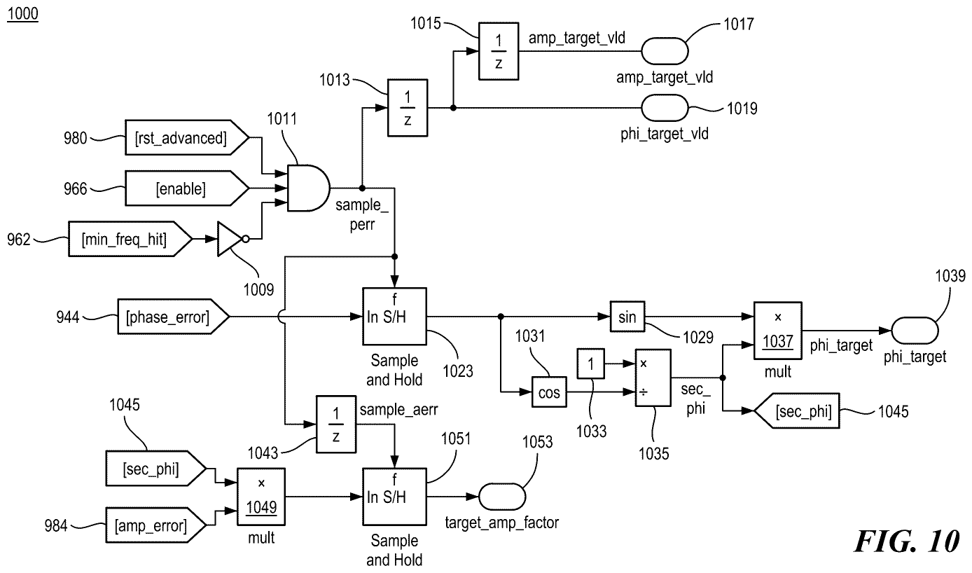

One example implementation of correction factor calculator 830 is shown in FIG. 10, and will be further discussed below.

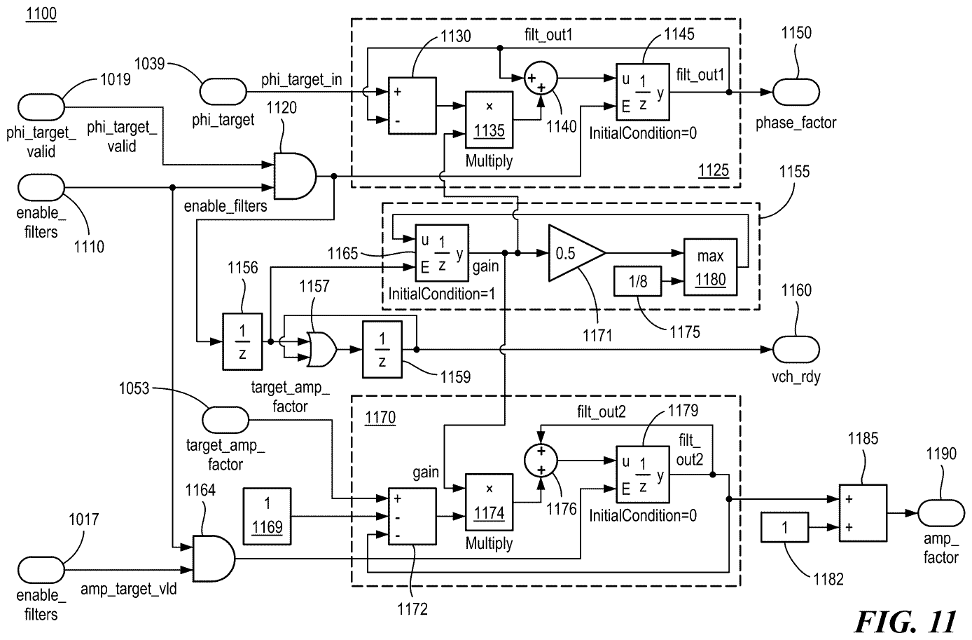

System 800 may also include filter 840. Filter 840 may be implemented in hardware (e.g., in digital and/or analog circuitry) or in software. Filter 840 may receive the target “B” (shown in FIG. 8 as “B_{target}”) and “C” (shown in FIG. 8 as “C_{target}”) values from correction factor calculator 830, and may filter the target values and output signals 843, 845 representing correction factor values “B” and “C,” respectively, for generating the virtual channel. One example implementation of filter 840 is shown in FIG. 11, and will be further discussed below.

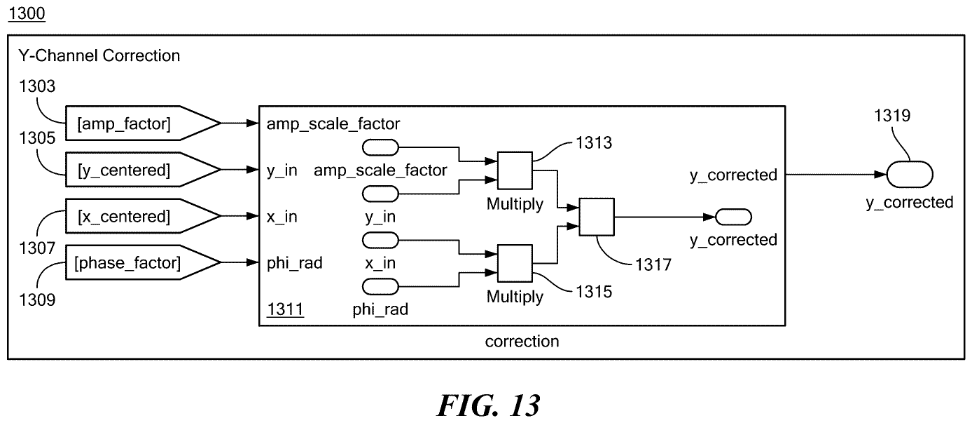

System 800 may also include virtual channel generator 850. Virtual channel generator 850 may be implemented in hardware (e.g., in digital and/or analog circuitry) or in software. Virtual channel generator 850 may generate a virtual channel signal 855 (e.g., Y_{corrected}) using correction factor values “B” and “C.” One example implementation of virtual channel generator 850 is shown in FIG. 13, and will be further discussed below. As shown in FIG. 8, virtual channel generator 850 may output a virtual channel signal 855 (e.g., Y_{corrected}) that is orthogonal to one of the measured magnetic field channel signals (e.g., “X”), that has been amplitude corrected to have the same amplitude as the measured magnetic field channel signal (e.g., X), and/or that has been offset corrected to have the same offset as the measured magnetic field channel signal (e.g., X). Virtual channel signal 855 may then be used to generate an angle signal, as previously discussed.

FIGS. 9A and 9B show diagrams of example parts of an example system 900 for extracting an amplitude and phase error between two measured magnetic field channel signals, consistent with embodiments of the present disclosure. System 900 may correspond to amplitude and phase error extractor 820 of FIG. 8, though the disclosure is not so limited.

An enable signal 964 may be received from another system within the sensor device (e.g., another circuit block within digital controller 120) to enable or disable the circuitry of system 900. For example, a logic high level (e.g., “1”) of the enable signal may enable operation of the system, while a logic low level (e.g., “0”) of the enable signal may disable operation of the system.

An amplitude error extractor circuit 911 of system 900 is an example circuit for extracting an amplitude error between two measured magnetic field channel signals (e.g., signals 109A, 109B of FIG. 1, signals 803, 805 of FIG. 8). A divider circuit 983 of amplitude error extractor circuit 911 may receive a value of a detected peak of the first measured magnetic field channel signal (X) (Xₚₑₐₖ) 981 and a value of a detected peak of the second measured magnetic field channel signal (Y) (Yₚₑₐₖ) 982. Divider circuit 983 may divide the received value of the detected peak of the first measured magnetic field channel signal (X) (Xₚₑₐₖ) 981 by the value of the detected peak of the second measured magnetic field channel signal (Y) (Yₚₑₐₖ) 982 and output the result as a signal 984 representing the amplitude error (A).

A phase error extractor circuit may be implemented using circuits 903, 905, 907, 913, and 915, as just one example. For example, circuit 903 may implement a first counter that holds a time difference between a peak (e.g., Xₚₑₐₖ 813) of the first measured magnetic field channel signal (X) (e.g., signal 109A, 803) and a peak (e.g., Yₚₑₐₖ 815) of the second measured magnetic field channel signal (Y) (e.g., signal 109B, 805). For example, in addition to outputting a value of a peak (Xₚₑₐₖ 813) of the first measured magnetic field channel signal and a value of a peak (Yₚₑₐₖ 815) of the second measured magnetic field channel signal, peak detector and offset detector and corrector 810 may output a logic high value (e.g., “1”) as a signal 902 (represented in FIG. 9A as “x_ppeak_evnt”)) when a positive peak has been reached in the first measured magnetic field channel signal, and a logic high value (e.g., “1”) as a signal 916 (represented in FIG. 9A as “y_ppeak_evnt”)) when a positive peak has been reached in the second measured magnetic field channel signal. Signal 902 (x_ppeak_evnt) may be input to an OR gate 906, the output of which may be input to an enable port (E) of a unit delay circuit 908. A person of ordinary skill in the art would understand that there are known techniques for implementing a unit delay circuit, and any of those techniques should be considered to be within the scope of the disclosure herein. As just one example, a unit delay circuit may be implemented with one or more flip flops.

When enabled, unit delay circuit 908 may hold and delay data input at its “u” port by one sample period. The sample period may correspond to one clock cycle of a system clock (e.g., a system clock of digital controller 120 or digital controller 1420). When the data input at the “u” port of unit delay circuit 908 is at a logic high (e.g., “1”) level, unit delay circuit 908 may output a logic high (e.g., “1”) level signal 910 (represented in FIG. 9A as “[up]”) at port “y.”

Similarly, signal 916 (y_ppeak_evnt) may be input to an OR gate 918, the output of which may be input to an enable port (E) of a unit delay circuit 920. When enabled, unit delay circuit 920 may hold and delay input data at its “u” port by one sample period. The sample period may correspond to one clock cycle of a system clock (e.g., a system clock of digital controller 120 or digital controller 1420). When the data input at the “u” port of unit delay circuit 920 is at a logic high (e.g., “1”) level, unit delay circuit 920 may output a logic high (e.g., “1”) level signal 922 (represented in FIG. 9A as “[dn]”) at port “y.”

Signal 910 (“[up]”) and signal 922 (“[dn]”) may be input into circuit 915. Circuit 915 may be used to determine whether to utilize a negative peak event (i.e., trough) of the first measured magnetic field channel (X) (e.g., signal 803) or a negative peak event (i.e., trough) of the second measured magnetic field channel (Y) (e.g., signal 805) to reset the unit delay circuits (e.g., unit delay circuit 908, unit delay circuit 920) and counter circuit 932 of circuit 903. Circuit 915 may allow the rest of the phase extractor circuit to operate correctly regardless of which direction the target is rotating. That is, circuit 915 may allow for bidirectional operation, and may switch whether a negative peak event (i.e., trough) of the first measured magnetic field channel signal (X) (e.g., signal 803) or a negative peak event (i.e., trough) of the second measured magnetic field channel signal (Y) (e.g., signal 805) should be used as a reset signal based on a direction of rotation of the target.

For example, as shown in FIG. 9B, a circuit 915 may include a number of NOT gates 987, 988, and 991, a number of AND gates 989, 990, and 993, an OR gate 992, and a unit delay circuit 994. The arrangement of these components in circuit 915 may result in an output for signal 970 (represented in FIG. 9B as “[up_dnb_latched]”) shown in Table 1 for corresponding input values of signals 985 (“[up]”) and 986 (“[dn]”) shown in Table 1.

TABLE 1

| [up] | [dn] | [up_dnb_latched] |
|---|---|---|
| 0 | 0 | maintain current |
| | | [up_dnb_latched] |
| 0 | 1 | 0 |
| 1 | 0 | 1 |
| 1 | 1 | maintain current |
| | | [up_dnb_latched] |

That is, when neither positive peak event (x_ppeak_evnt or y_ppeak_evnt) has occurred in a rotational period, the current state of [up_dnb_latched] may be maintained. Similarly, when both positive peak events (x_ppeak_evnt and y_ppeak_evnt) have occurred simultaneously in a rotational period, the current state of [up_dnb_latched] may be maintained. When a positive peak event (x_ppeak_evnt) has not occurred in the first measured magnetic field channel signal (X) in a rotational period, but a positive peak event (y_ppeak_evnt) has occurred in the second measured magnetic field channel signal (Y) in the rotational period, a logic low value (e.g., “0”) may be output for signal 970 ([up_dnb_latched]). When a positive peak event (x_ppeak_evnt) has occurred in the first measured magnetic field channel signal (X) in a rotational period, but a positive peak event (y_ppeak_evnt) has not occurred in the second measured magnetic field channel signal (Y) in the rotational period, a logic high value (e.g., “1”) may be output for signal 970 ([up_dnb_latched]).

Signal 970 may then be input into circuitry 913. Circuitry 913 may also receive signals indicating whether negative peak events have occurred in the first measured magnetic field channel signal (X) (e.g., signal 803) or in the second measured magnetic field channel signal (Y) (e.g., signal 805). For example, in addition to outputting a value of a peak (Xₚₑₐₖ 813) and an indication of whether a positive peak has been reached in the first measured magnetic field channel signal (X) (e.g., signal 803), peak detector and offset detector and corrector 810 may also output a logic high value (e.g., “1”) as a signal 968 (represented in FIG. 9B as “x_npeak_evnt”) when a negative peak (i.e., trough) has been reached in the first measured magnetic field channel signal in a rotational period of the target. Also, in addition to outputting a value of a peak (Yₚₑₐₖ 815) and an indication of whether a positive peak has been reached in the second measured magnetic field channel signal (Y) (e.g., signal 805), peak detector and offset detector and corrector 810 may also output a logic high value (e.g., “1”) as a signal 972 (represented in FIG. 9B as “y_npeak_evnt”) when a negative peak (i.e., trough) has been reached in the second measured magnetic field channel signal in a rotational period of the target. Switching circuitry 974 may receive signals 968, 970, and 972, and may determine whether to use signal 968 (x_npeak_evnt) or signal 972 (y_npeak_evnt) as the trigger for resetting unit delay circuits 908, 920 and counting circuitry 932, 950 in circuits 903 and 905. For example, when signal 970 is at a logic high level (e.g., “1”), signal 970 may configure switching circuitry 974 to use signal 968 (x_npeak_evnt) as the trigger for reset signals 930 (represented in FIGS. 9A and 9B as “[rst]”) and 980 (represented in FIG. 9B as “[rst_advanced]”). When signal 970 is at a logic low level (e.g., “0”), signal 970 may configure switching circuitry 974 to use signal 972 (y_npeak_evnt) as the trigger for reset signals 930 ([rst]) and 980 ([rst_advanced]). Signal 980 may be a reset signal ([rst_advanced]) that is triggered as soon as a logic high value (e.g., “1”) is output from switching circuitry 974, while signal 930 may be a reset signal ([rst]) that is triggered after the logic high value (e.g., “1”) output from switching circuitry 974 has been delayed by a sample period (e.g., system clock cycle) by unit delay circuitry 976.

Signal 930 ([rst]) may be input to an OR gate 912 in circuit 903. OR gate 912 may also receive an input from AND gate 926, which receives signal 910 ([up]) and signal 922 ([dn]). Thus, when either signal 930 ([rst]) or both signal 910 ([up]) and signal 922 ([dn]) are at a logic high level (e.g., “1”), OR gate 912 may output a signal with a logic high value (e.g., “1”), which is then input to NOT gates 904, 914, resetting the data in unit delay circuits 908, 920 to a logic low level (e.g., “0”).

Signal 910 ([up]) and signal 922 ([dn]) may be input to an OR gate 928. Thus, when either of signal 910 ([up]) and signal 922 ([dn]) are at a logic high value (e.g., “1”), OR gate 928 may output a signal at a logic high value (e.g., “1”) to counter circuitry 932, and counter circuitry 932 may count clock signals from a clock (e.g., system clock, such as the clock from clock generation circuit 1422) to count a period of time starting from the positive peak of the first measured magnetic field channel signal (X) (e.g., signal 803) or the positive peak of the second measured magnetic field channel signal (Y) (e.g., signal 805) (whichever occurs earlier). Counter circuitry 932 may be reset each rotational period of the target by signal 930 ([rst]). The output of counter circuitry 932 may be output as a signal (represented in FIG. 9A as “pulse_cnt”) to multiplier circuitry 934. Since perfectly orthogonal channel signals are phase-shifted from each other by ninety degrees, multiplier circuitry 934 may multiply the value of the signal output from counter circuitry 932 (pulse_cnt) by four to normalize it to a full rotational period of the target.

Circuit 905 may implement a second counter that holds a time difference between two peaks of the same measured magnetic field channel signal. For example, when signal 930 is at a logic high level (e.g., “1”), counter circuitry 950 may be reset, and then when signal 930 returns to a logic low level (e.g., “0”), counter circuitry 950 may begin to count clock pulses so long as a predetermined minimum frequency of rotation of the target has not been met. The output of the counted pulses may be output from counter circuitry 950 to subtraction circuitry 952. Subtraction circuitry 952 may subtract a value 954 (e.g., −2) from the number of counted pulses as a bias to correct for a missed cycle in counter circuitry 932, which may occur as a result of loopbacks and/or delays. Subtraction circuitry 952 may output a signal with the result of the subtraction, the signal representing a value corresponding to the rotational period of the target. Circuitry 958 may compare this value to a maximum period value 956 to determine whether the value corresponding to the rotational period of the target is greater than or equal to a maximum period value. If the value corresponding to the rotational period of the target is greater than or equal to maximum period value 956, a signal (represented in FIG. 9 as “min_freq_hit”) indicating that a minimum frequency of rotation of the target has been hit may be output to a unit delay circuit 960. Unit delay circuitry 960 may then output the signal indicating that the minimum frequency of rotation has been hit as signal 962 ([min_freq_hit]), which may be fed back to a NOT gate 946 connected to an increment port of counter circuitry 950, so that a logic high level (e.g., “1”) of signal 962 causes the increment port to receive a logic low level (e.g., “0”) and to no longer count. That is, circuitry 958 and 960 of circuit 905 may cause the time difference between two peak events of the same measured magnetic field channel signal to not be tracked when the frequency of rotation of the target is too low. For example, the circuit of system 900 may work for rotation speeds of a target down to a certain limit (which may be dictated by the number of bits in counter circuitry 950 and/or counter circuitry 932). If the rotation speed of the target is lower than this limit, counter circuitry 950 and/or counter circuitry 932 may saturate. As a result, maximum period value 956 may be set, so that once this minimum frequency of rotation of the target has been hit, counter circuitry 932 and/or counter circuitry 950 may stop incrementing, and an error or warning may be output to a controller.

Subtraction circuitry 936 in circuit 907 may subtract the value of the signal corresponding to the rotational period of the target from the value of the normalized signal from multiplier circuitry 934, and divider circuitry 938 may divide the value of the resulting signal by the value of the signal corresponding to the rotational period of the target to get an output signal with a value representing the phase error normalized to one quarter of a full rotational period of the target. This value representing the phase error may be wrapped around if it exceeds 1 or goes below −1 by wrapping circuitry 940, and may be scaled by pi/2 by circuitry 942 to obtain the phase error in units of radians, which may be output as signal 944 (represented in FIG. 9A as “[phase_error]”).

The amplitude error value of signal 984 ([amp_error]) and phase error value of signal 944 ([phase_error]) may be output as signals 823 (A) and 825 (phi) respectively to a correction factor calculator 830.

FIG. 10 shows a diagram of an example system 1000 for implementing a correction factor calculator, consistent with embodiments of the present disclosure. System 1000 may correspond to correction factor calculator 830 of FIG. 8, though the disclosure is not so limited. System 1000 may be used to calculate a target error correction value of B and a target error correction value of C in accordance with Equations 16 and 17.

A secant of the phase error (e.g., signal 825 (phi), signal 944 ([phase_error])) may be calculated and input as signal 1045. For example, as previously discussed, the secant of the phase error may be calculated using Pade's approximation, such as in accordance with Equation 18 above. A person of ordinary skill in the art would recognize that there are known techniques using software and/or digital logic circuitry to calculate Pade's approximation, and any of these known techniques should be considered to be within the scope of the disclosure herein. In some embodiments, the secant of the phase error may be calculated using Taylor series expansion. A person of ordinary skill in the art would recognize that there are known techniques utilizing software and/or digital logic circuitry to approximate a value by calculating a Taylor series expansion, and any of these known techniques should be considered to be within the scope of the disclosure herein. Of course, there are other known techniques for calculating a value of a secant function, and any of these known techniques may be used to approximate the value of signal 1045 ([sec_phi]).

A signal 823 representing amplitude error (A) may be input to system 1000 as signal 984 ([amp_error]), which may be signal 984 determined by system 900 of FIGS. 9A, 9B. Multiplier circuitry 1049 may multiply the value of signal 1045 ([sec_phi]) with the value of signal 984 ([amp_error]). Note that, in Equations 3, 5-7, 9, 10, and 12-17 above, the amplitude error value was calculated as the peak amplitude of Y divided by the peak amplitude of X, while in the schematic of FIGS. 9A, 9B, the amplitude error value was determined as the peak amplitude of X divided by the peak amplitude of Y. That is, the value of signal 984 ([amp_error]) of system 900 is the reciprocal of the value of A in Equation 16. Thus, multiplication of the value of signal 984 ([amp_error]) with the value of signal 1045 ([sec_phi]) is equivalent to Equation 16. The resulting value output by multiplier circuitry 1049 may be sampled and held by sample and hold circuitry 1051, and output as a signal 1053 representing a value of target amplitude correction factor B (e.g., B_{target} of FIG. 8), in accordance with Equation 16 above.

A signal 825 representing phase error (phi) may be input to system 1000 as signal 944 ([phase_error]), which may be signal 944 determined by system 900 of FIGS. 9A, 9B. The value of signal 944 may be sampled and held by sample and hold circuitry 1023.

Circuitry 1029 may calculate a sine value of the value output from sample and hold circuitry 1023 and may output the resulting value as a signal to multiplier circuitry 1037. Circuitry 1031 may calculate a cosine value of the value output from sample and hold circuitry 1023 and may output the resulting value to circuitry 1035, which may determine the secant (e.g., 1/cos(φ)) of the value output from sample and hold circuitry 1023 by dividing a value 1033 of “1” by the cosine value output from circuitry 1031. As discussed previously, circuitry 1035 may determine this secant value by performing Pade's approximation, Taylor series expansion, or any other known technique for determining a secant of a value in software and/or in digital logic circuitry. Circuitry 1035 may output a signal 1045 (represented in FIG. 10 as “[sec_phi]”) representative of the secant of the phase error, which may be input to multiplier circuitry 1037 and multiplier circuitry 1049. Multiplier circuitry 1037 may then multiply the value of signal 1045 ([sec_phi]) by the value of the signal output from 1029 to obtain a signal 1039 representing a value of phase correction factor C (e.g., C_{target} of FIG. 8), in accordance with Equation 17 above.

Signals 980 ([rst_advanced]), 966 ([enable]), and 962 ([min_freq_hit]) may be input to system 1000 and utilized to control sample and hold circuitry 1023 and sample and hold circuitry 1051. Signals 980, 966, and 962 may be signals 980, 966, and 962 generated by system 900 of FIGS. 9A, 9B.

An AND gate 1011 may receive signal 980 ([rst_advanced]) as an input. AND gate 1011 may also receive signal 966 ([enable]) as an input. Signal 962 ([min_freq_hit]) may also be input and passed through a NOT gate 1009 and then into AND gate 1011. Thus, when signal 966 ([enable]) is at a logic high level (e.g., “1”) (indicating that the system is enabled), signal 980 ([rst_advanced]) is at a logic high level (e.g., “1”) (indicating that a sample period has completed), and the signal output from NOT gate 1009 is at a logic high level (e.g., “1”) (indicating that signal 962 ([min_freq_hit]) is at a logic low value (e.g., “0”) and that a minimum rotation frequency of the target has not been hit), signal 944 ([phase_error]) may be sampled and held by sample and hold circuitry 1023, and the signal output from multiplier circuit 1049 may be sampled and held by sample and hold circuitry 1051 (after a delay of a sample cycle by unit delay circuit 1043 to allow signal 1045 to first be calculated). The output from AND gate 1011 may also be output to unit delay circuits 1013, 1015, the outputs of which may be output as signals 1017 (represented in FIG. 9 as “amp_target_vld”) and 1019 (represented in FIG. 9 as “phi_target_vld”). A logic high value (e.g., “1”) of signals 1017 and 1019 may indicate to the components of the sensor device that signal 1039 (phi_target) and signal 1053 (target_amp_factor), respectively, are valid and can be relied upon.

Signal 1053 (target_amp_factor) may be output as signal 833 (B_{target}), and signal 1039 (phi_target) may be output as signal 835 (C_{target}), to filter 840.

FIG. 11 shows a diagram of an example system 1100 for implementing a filter, consistent with embodiments of the present disclosure. System 1100 may correspond to filter 840 of FIG. 8, though the disclosure is not so limited. System 1100 may be used to filter the target amplitude correction factor (e.g., B_{target}, signal 833, signal 1053) and to filter the target phase correction factor (e.g., C_{target}, signal 835, signal 1039). In some embodiments, the filter may be a dynamic bandwidth filter, where the filter has a large bandwidth at startup and then the bandwidth decreases in a few sampling cycles to be narrower in steady-state and to filter out noise that may occur within the computations, as the correction factors are not expected to vary significantly over time.

System 1100 may receive signal 1039 (phi_target). Signal 1039 may be signal 1039 determined by system 1000 of FIG. 10. Signal 1039 (phi_target) may be input into low pass filter circuitry 1125. Subtraction circuitry 1130 may subtract a value of a phase correction factor of signal 1150 (shown in FIG. 11 as “filt_out1” or “phase_factor”) filtered in the previous sampling cycle from the value of signal 1039 (phi_target), and may output the resulting value as a signal into multiplier circuitry 1135. Multiplier circuitry 1135 may multiply the value of the signal from subtraction circuitry 1130 with a value from unit delay circuit 1165 of scale factor circuitry 1155, and may output the resulting value as a signal input to addition circuitry 1140. Addition circuitry 1140 may add the value from multiplier circuitry 1135 to the value of the phase correction factor filtered in the previous sampling cycle in signal 1150 (“filt_out1” or “phase_factor”), and may output the resulting value as a signal input to unit delay circuit 1145. Unit delay circuit 1145, when enabled, may delay outputting the resulting value by one sampling cycle, and then may output the resulting value as the new value of signal 1150 (“filt_out1” or “phase_factor”). The value of signal 1150 (“filt_out1” or “phase_factor”) may be output as the filtered phase correction factor (e.g., signal 845 (“C”) of FIG. 8).

System 1100 may also receive signal 1053 (target_amp_factor). Signal 1053 may be signal 1053 determined by system 1000 of FIG. 10. Signal 1053 (target_amp_factor) may be input into low pass filter circuitry 1170. Subtraction circuitry 1172 may subtract a value of signal 1169 (“1”) and a value of an amplitude error value (shown in FIG. 11 as “filt_out2”) filtered in the previous sampling cycle from the value of signal 1053 (target_amp_factor), and may output the resulting value as a signal to multiplier circuitry 1174. Multiplier circuitry 1174 may multiply the value of the signal from subtraction circuitry 1172 with a value from unit delay circuit 1165 of scale factor circuitry 1155, and may output the resulting value as a signal input to addition circuitry 1176. Addition circuitry 1176 may add the value from multiplier circuitry 1174 to the value of the amplitude error value (“filt_out2”) filtered in the previous sampling cycle, and may output the resulting value as a signal input to unit delay circuit 1179. Unit delay circuit 1179, when enabled, may delay outputting the resulting value by one sampling cycle, and then may output the resulting value as the new value of the “filt_out2” signal. The new value of the “filt_out2” signal may be output to addition circuitry 1185. Addition circuitry 1185 may add the value of the “filt_out2” signal to the value of signal 1182 (“1”), and output the resulting value as signal 1190 (“amp_factor”). The value of signal 1190 (“amp_factor”) may be output as the filtered amplitude correction factor (e.g., signal 843 (“B”) of FIG. 8).

FIG. 11 also illustrates example enable circuitry for system 1100. For example, an AND gate 1120 may be provided that receives a signal 1019 (illustrated in FIG. 11 as “phi_target_valid”) and a signal 1110 (illustrated in FIG. 11 as “enable_filters”). Signal 1019 may be signal 1019 determined by system 1000 of FIG. 10. Signal 1110 may be a signal received from other circuitry of the sensor device (e.g., other circuitry of digital controller 120) that enables or disables the filtering circuitry of system 1100. When signal 1019 (phi_target_valid) is at a logic high level (e.g., “1”) indicating that the phi target value of signal 1039 is valid, and when signal 1110 (enable_filters) is at a logic high level (e.g., “1”) indicating that the filtering circuitry of system 1100 is enabled, AND gate 1120 may output a signal having a logic high level (e.g., “1”), thereby enabling unit delay circuit 1145 of low pass filter circuit 1125.

Similarly, an AND gate 1164 may be provided that receives a signal 1017 (illustrated in FIG. 11 as “amp_target_vld”) and signal 1110 (enable_filters). Signal 1017 may be signal 1017 determined by system 1000 of FIG. 10. When signal 1017 (amp_target_vld) is at a logic high level (e.g., “1”) indicating that the target_amp_factor value of signal 1053 is valid, and when signal 1110 (enable_filters) is at a logic high level (e.g., “1”) indicating that the filtering circuitry of system 1100 is enabled, AND gate 1164 may output a signal having a logic high level (e.g., “1”), thereby enabling unit delay circuit 1179 of low pass filter circuit 1170.

The signal output from AND gate 1120 may also be input to a unit delay circuit 1156. After being delayed by one sampling cycle, the signal may be input to an enable port of unit delay circuit 1165 of scale factor circuit 1155.

Scale factor circuit 1155 may scale the bandwidth of the filtering circuitry of system 1100. For example, scale factor circuit 1155 may generate a sequence of gains that operates to reduce the bandwidth of the filter until it reaches a steady-state. Initially, for example, unit delay circuit 1165 may output a signal with a value of the gain of 1. This signal may be input to multiplier circuit 1135 of low pass filter circuit 1125 and to multiplier circuit 1174 of low pass filter circuit 1170. The gain signal may be input to a multiplier circuit 1171 that multiplies the value of the gain signal by 0.5. A circuit 1180 (e.g., comparator) may receive the signal output from multiplier circuit 1171 and a signal 1175 (e.g., ⅛), and may compare the signal output from multiplier circuit 1171 to the value of signal 1175. If the value of the signal output from multiplier circuit 1171 is greater than the value of signal 1175 (e.g., ⅛), the value of the signal output from multiplier circuit 1171 (now 0.5) may be input to the “u” port of unit delay circuit 1165. In the next sampling cycle, unit delay circuit 1165 may output the new gain signal (e.g., 0.5), which may be input to multiplier circuit 1135 of low pass filter circuit 1125 and to multiplier circuit 1174 of low pass filter circuit 1170. This may continue, such that the gain signal in the next sampling cycle is 0.25, and the gain signal in the following sampling cycle is 0.125. Once the signal output from multiplier circuit 1171 is less than 0.125 (i.e., ⅛), circuit 1180 (e.g., comparator) may determine that the signal is less than 0.125 and may hold the value at 0.125, such that the gain signal output from unit delay circuit 1165 remains 0.125 in subsequent sampling cycles.

The output of unit delay circuit 1156 may also be output to an OR gate 1157. The output of OR gate 1157 may be input to a unit delay circuit 1159. The output of unit delay circuit 1159 may be a signal 1160 (illustrated in FIG. 11 as “vch_ready”). The output of unit delay circuit 1159 may also be fed back as another input to OR gate 1157. Thus, one sampling cycle after the output of unit delay circuit 1156 is at a logic high level (e.g., “1”) or the output of unit delay circuit 1159 is at a logic high level (e.g., “1”), signal 1160 may be at a logic-high level (e.g., “1”), indicating that signal 1150 (phase_factor) and signal 1190 (amp_factor) have been output and that the virtual channel is ready to be determined.

Thus, the filtering circuitry of system 1100 may function as a dynamic bandwidth filter, which has a large bandwidth at startup (e.g., when the gain signal is “1”), and in which the bandwidth decreases over the course of the next cycles to be narrow in steady-state and to filter out noise that may occur within the computations of signal 1039 (phi_target) and signal 1053 (target_amp_factor). The bandwidth decreases over sampling cycles, as this filtering correction may be expected to not need to vary significantly over time.

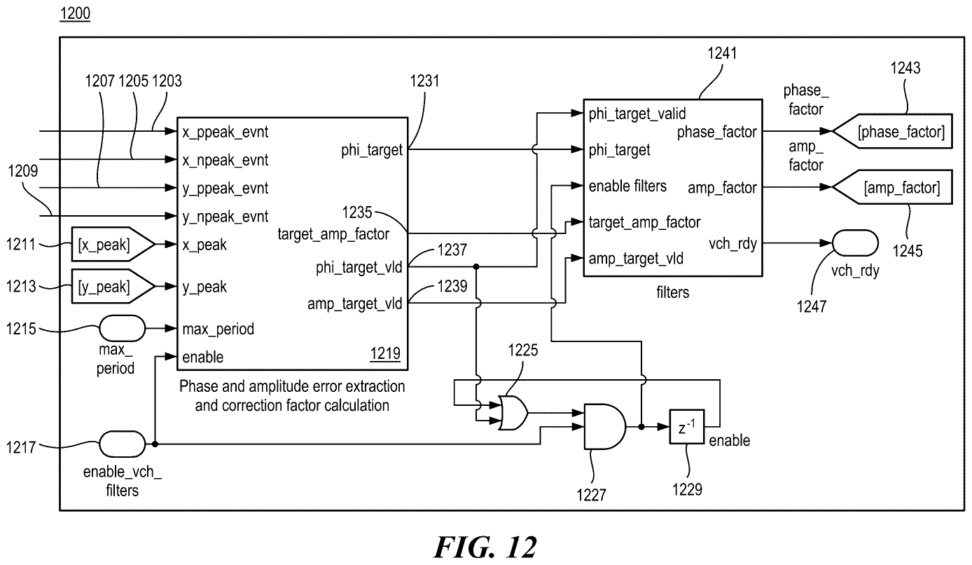

FIG. 12 shows a diagram of an example system 1200 that includes a phase and amplitude error extraction and correction factor calculator circuit 1219 and a filter circuit 1241, consistent with embodiments of the present disclosure. For example, phase and amplitude error extraction and correction factor calculator circuit 1219 may include amplitude and phase error extractor 820 and correction factor calculator 830 of FIG. 8, system 900 of FIGS. 9A, 9B, and/or system 1000 of FIG. 10. Filter circuit 1241 may include filter 840 of FIG. 8 and/or system 1100 of FIG. 11.

As shown in FIG. 12, phase and amplitude error extraction and correction factor calculation circuit 1219 may receive a signal 1203 (illustrated in FIG. 12 as “x_ppeak_evnt”), a signal 1205 (illustrated in FIG. 12 as “x_npeak_evnt”), a signal 1207 (illustrated in FIG. 12 as “y_ppeak_evnt”), a signal 1209 (illustrated in FIG. 12 as “y_npeak_evnt”), a signal 1211 (illustrated in FIG. 12 as “[x_peak]”), a signal 1213 (illustrated in FIG. 12 as “[y_peak]”), a signal 1215 (illustrated in FIG. 12 as “max_period”), and a signal 1217 (illustrated in FIG. 12 as “enable_vch_filters”). For example, signal 1203 (x_ppeak_evnt) may be the same signal as signal 902 (x_ppeak_evnt) of system 900 of FIGS. 9A, 9B, signal 1205 (x_npeak_evnt) may be the same signal as signal 968 (x_npeak_evnt) of system 900 of FIGS. 9A, 9B, signal 1207 (y_ppeak_evnt) may be the same signal as signal 916 (y_ppeak_evnt) of system 900 of FIGS. 9A, 9B, and signal 1209 may be the same signal as signal 972 (y_npeak_evnt) of system 900 of FIGS. 9A, 9B. Signal 1211 ([x_peak]) may be the same signal as signal 981 (x_peak) of system 900 of FIGS. 9A, 9B, and signal 1213 ([y_peak]) may be the same signal as signal 982 (y_peak) of system 900 of FIGS. 9A, 9B. Signal 1215 (max_period) may be the same signal as signal 956 (max_period) of system 900 of FIGS. 9A, 9B, and signal 1217 may be the same signal as signal 964 (enable) of system 900 of FIGS. 9A, 9B.

Phase and amplitude error extraction and correction factor circuitry 1219 may output a signal 1231 (illustrated in FIG. 12 as “phi_target”), a signal 1235 (illustrated in FIG. 12 as “target_amp_factor”), a signal 1237 (illustrated in FIG. 12 as “phi_target_vld”), and a signal 1239 (illustrated in FIG. 12 as “amp_target_vld”). For example, signal 1231 (phi_target) may be the same signal as signal 1039 (phi_target) of system 1000 of FIG. 10, signal 1235 (target_amp_factor) may be the same signal as signal 1053 (target_amp_factor) of system 1000 of FIG. 10, signal 1237 (phi_target_vld) may be the same signal as signal 1019 (phi_target_vld) of system 1000 of FIG. 10, and signal 1239 (amp_target_vld) may be the same signal as signal 1017 (amp_target_vld) of system 1000 of FIG. 10.

Signal 1231 (phi_target), signal 1235 (target_amp_factor), signal 1237 (phi_target_vld), and/or signal 1239 (amp_target_vld) may be input to filter circuitry 1241.

An OR gate 1225 may receive signal 1237 (phi_target_vld) and may output a signal to AND gate 1227. AND gate 1227 may also receive signal 1217 (enable_vch_filters) as an input. When the output of OR gate 1225 and signal 1217 are both at a logic high level (e.g., “1”), AND gate 1227 may output a logic high level (e.g., “1”) signal, which may be input as an “enable_filters” signal to filter circuitry 1241. The “enable“filters” signal may be the same signal as signal 1110 (enable_filters) of system 1100 of FIG. 11, for example. The output of AND gate 1227 may also be input to a unit delay circuit 1229, which may delay the signal by one sample cycle and output the delayed signal in a feedback loop to OR gate 1225.

In some embodiments, filter circuitry 1241 may include system 1100 of FIG. 11.

Filter circuitry 1241 may output a signal 1243 (illustrated in FIG. 12 as “[phase_factor]”), a signal 1245 (illustrated in FIG. 12 as “[amp_factor]”), and a signal 1247 (illustrated in FIG. 12 as “vch_rdy”). For example, signal 1243 (“[phase_factor]”) may be the same signal as signal 1150 (“phase_factor”) of system 1100 of FIG. 11, signal 1245 (“[amp_factor]”) may be the same signal as signal 1190 (“amp_factor”) of system 1100 of FIG. 11, and signal 1247 (“vch_rdy”) may be the same signal as signal 1160 (“vch_rdy”) of system 1100 of FIG. 11.

FIG. 13 shows a diagram of an example system 1300 that includes a circuit for generating a virtual channel based on offset-adjusted measured magnetic field channel signals and correction factors. System 1300 may correspond, for example, to virtual channel generator 850 of FIG. 8.

System 1300 may receive signal 1303 (illustrated in FIG. 13 as “[amp_factor]”), signal 1309 (illustrated in FIG. 13 as “[phase_factor]”), signal 1305 (illustrated in FIG. 13 as “[y_centered]”), and signal 1307 (illustrated in FIG. 13 as “[x_centered]”).

Signal 1303 ([amp_factor]) may be the same signal as signal 1245 ([amp_factor]) of system 1200 of FIG. 12, and/or as signal 843 (“B” correction factor) of system 800 of FIG. 8. Signal 1309 ([phase_factor]) may be the same signal as signal 1243 ([phase_factor]) of system 1200 of FIG. 12 and/or as signal 845 (“C” correction factor) of system 800 of FIG. 8.

Signal 1305 ([y_centered]) may correspond to an offset-corrected version of one of the measured channel signals (e.g., signal 109B, signal 540 (“Right”), signal 740 (“R”), signal 805 (“Y”), signal 1426 (“Y”)). For example, the measured channel signal (e.g., signal 109B, signal 540 (Right), signal 740 (R), signal 805 (Y), signal 1426 (Y) may be corrected for any offsets from a predetermined value around which the sinusoidal channel signal should oscillate using the offset detected in peak detector and offset detector and corrector 810, and the resulting signal may be output as signal 1305 ([y_centered]).

Signal 1307 ([x_centered]) may correspond to an offset-corrected version of the other of the measured channel signals (e.g., signal 109A, signal 530 (“Left”), signal 735 (“L”), signal 803 (“X”), signal 1427 (“X”)). For example, the other measured channel signal (e.g., signal 109A, signal 530 (Left), signal 735 (L), signal 803 (X), signal 1427 (X) may be corrected for any offsets from a predetermined value around which the sinusoidal channel signal should oscillate using the offset detected in peak detector and offset detector and corrector 810, and the resulting signal may be output as signal 1307 ([x_centered]).

Multiplier circuit 1313 may receive signal 1303 ([amp_factor]) and signal 1305 ([y_centered]) and may multiply them together and output the result. Multiplier circuit 1315 may receive signal 1309 ([phase_factor]) and signal 1307 ([x_centered]) and may multiply them together and output the result. Addition circuit 1317 may add the result from multiplier circuit 1313 and the result from multiplier circuit 1315 and output the result as virtual channel signal 1319 (illustrated in FIG. 13 as “y_corrected”). That is, multiplier circuit 1313, multiplier circuit 1315, and addition circuit 1317 may operate together to determine the virtual channel signal (Y_{corrected}) as shown above in Equation 10.

A person of ordinary skill in the art would understand how to implement components discussed above in analog and/or digital circuitry. For example, a person of ordinary skill in the art would recognize that there are a variety of techniques for constructing circuit components such as NOT gates, AND gates, OR gates, unit delay circuits, counters, addition circuits, subtraction circuits, multiplier circuits, division circuits, wrapping circuits, switches, sample and hold circuits, sine calculation circuits, cosine calculation circuits, and secant calculation circuits. Any known technique for constructing these components should be considered to be within the scope of the disclosure herein.

Additionally, although specific example circuits are illustrated in FIGS. 9A-13, these circuits are just examples and the disclosure should not be limited to these examples. A person of ordinary skill in the art would recognize that equivalent or similar functionality may be achieved with different circuit implementations using known techniques. As just one example, the circuits may be reconfigured such that various circuit components are triggered based on logic low level (e.g., “0”) signals rather than based on logic high level (e.g., “1”) signals, and the same or similar result achieved. Thus, alternative circuits that achieve the same or similar functionality using known techniques should be considered to be within the scope of the disclosure herein.

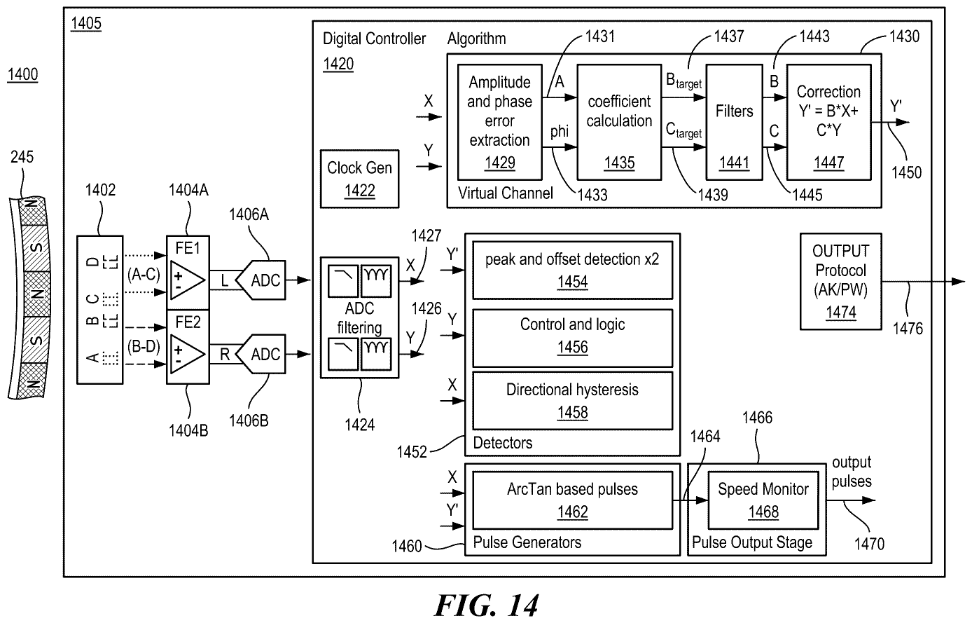

FIG. 14 shows a block diagram of an example system 1400 including a target 245 and a sensor device 1405, consistent with embodiments of the present disclosure. Target 245 may be the same target as target 101 of FIG. 1, or target 245 of FIG. 2, 3A, or 3B, though the disclosure is not so limited. Sensor device 1405 may be the same as sensor device 105 or sensor device 205, but with additional details shown, though the disclosure is not so limited.

Sensor device 1405 may include magnetic field sensing elements 1402. For example, FIG. 14 illustrates sensor device 1405 as including four magnetic field sensing elements 1402, magnetic field sensing element A, magnetic field sensing element B, magnetic field sensing element C, and magnetic field sensing element D. The magnetic field sensing elements may be any of the types of magnetic field sensing elements previously described with respect to FIG. 1, 2, or 7, for example, and may be arranged in any of the ways discussed above with respect to FIGS. 1, 2, and 7, for example. The magnetic field sensing elements may be configured to sense a magnetic field generated by a rotating target 245.

FIG. 14 illustrates the magnetic field sensing elements as being differentially paired. That is, magnetic field sensing elements A may be differentially paired with magnetic field sensing element C, such that one or more channel elements (e.g., front end amplifier (FE1) 1404A, ADC 1406A) may take a difference between the signals output from magnetic field sensing element A and magnetic field sensing element C and output the difference as a channel signal (e.g., left channel signal (L)). Similarly, magnetic field sensing element B may be differentially paired with magnetic field sensing element D, such that one or more channel elements (e.g., front end amplifier (FE2) 1404B, ADC 1406B) may take a difference between the signals output from magnetic field sensing element B and magnetic field sensing element D and output the difference as a channel signal (e.g., right channel signal (R)).

Sensor device 1405 may include a digital controller 1420. Digital controller may be the same as digital controller 120 of FIG. 1, but with additional details shown, though the disclosure is not so limited. In some embodiments, digital controller 1420 may include system 800 of FIG. 8, system 900 of FIGS. 9A, 9B, system 1000 of FIG. 10, system 1100 of FIG. 11, system 1200 of FIG. 12, and/or system 1300 of FIG. 13, though the disclosure is not so limited. Digital controller 1420 may configured as described with respect to digital controller 120 of FIG. 1, though the disclosure is not so limited.

Digital controller 1420 may comprise an ADC filtering block 1424. ADC filtering block 1424 may comprise, for example, one or more high pass filters, low pass filters, and/or notch filters for filtering left (L) and right (R) channel signals output out of ADCs 1406A, 1406B. For example, ADC filtering block 1424 may filter the left (L) channel signal and output a signal (X). ADC filtering block 1424 may filter the right (R) channel signal and output a signal (Y).

Digital controller 1420 may comprise detectors circuitry 1452. For example, detectors circuitry 1452 may include peak detection and offset detection and correction circuitry 1454 for each of the X and Y channel signals. Peak detection and offset detection and correction circuitry 1454 may be the same as peak detector and offset detector and corrector 810, though the disclosure is not so limited.

Detectors circuitry 1452 may also comprise directional hysteresis circuitry 1458. Directional hysteresis circuitry 1458 may be used to determine which direction a target (e.g., target 245) is rotating. Directional hysteresis circuitry 1458 may include, for example, circuit 915 of system 900 of FIG. 9, though the disclosure is not so limited.

Detectors circuitry 1452 may also include control and/or logic circuitry 1456. Control and/or logic circuitry 1456 may operate to control one or more of the circuit blocks of digital controller 1420, such as ADC filtering circuit 1424, detectors circuitry 1452, pulse generators circuitry 1460, pulse output stage circuitry 1466, virtual channel circuitry 1430, clock generator circuitry 1422, and/or output circuitry 1474.

Digital controller 1420 may also comprise virtual channel circuitry 1430. Virtual channel circuitry 1430 may comprise, for example, amplitude and/or phase error extractor 820 of system 800 of FIG. 8, correction factor calculator 830 of system 800 of FIG. 8, filter 840 of system 800 of FIG. 8, virtual channel generator 850 of system 800 of FIG. 8, system 900 of FIG. 9, system 1000 of FIG. 10, system 1100 of FIG. 11, system 1200 of FIG. 12, and/or system 1300 of FIG. 13.

Virtual channel circuitry 1430 may comprise amplitude and/or phase error extraction circuitry 1429, coefficient calculation circuitry 1435, filter circuitry 1441, and/or correction circuitry 1447. Amplitude and/or phase error extraction circuitry 1429 may comprise amplitude and/or phase error extractor 820 of system 800 of FIG. 8 and/or system 900 of FIG. 9, for example, though the disclosure is not so limited. As shown in FIG. 14, amplitude and/or phase error extraction circuitry 1429 may output a signal 1431 (illustrated in FIG. 14 as “A”) and a signal 1433 (illustrated in FIG. 14 as “phi”). Signal 1431 (A) may be the same as signal 823 (A) and/or signal 984 ([amp_error]), though the disclosure is not so limited. Signal 1433 (phi) may be the same as signal 825 (phi) and/or signal 944 ([phase_error]), though the disclosure is not so limited.

Virtual channel circuitry 1430 may also comprise coefficient calculation circuitry 1435. Coefficient calculation circuitry 1435 may comprise correction factor calculator 830 of system 800 of FIG. 8 and/or system 1000 of FIG. 10, for example, though the disclosure is not so limited. As shown in FIG. 14, coefficient calculation circuitry 1435 receive signal 1431 (A) and signal 1433 (phi), and may output a signal 1437 (illustrated in FIG. 14 as “B_{target}”) and a signal 1439 (illustrated in FIG. 14 as “C_{target}”). Signal 1437 (B_{target}) may be the same as signal 833 (Berget) and/or signal 1053 (target_amp_factor), though the disclosure is not so limited. Signal 1439 (C_{target}) may be the same as signal 835 (C_{target}) and/or signal 1039 (phi_target), though the disclosure is not so limited.

Virtual channel circuitry 1430 may also comprise filter circuitry 1441. Filter circuitry may comprise filter circuitry 840 of system 800 of FIG. 8 and/or system 1100 of FIG. 11, though the disclosure is not so limited. As shown in FIG. 14, filter circuitry 1441 may receive signal 1437 (B_{target}) and signal 1439 (C_{target}), and may output a signal 1443 (illustrated in FIG. 14 as “B”) and a signal 1445 (illustrated in FIG. 14 as “C”). Signal 1443 (B) may be the same as signal 843 (B) and/or signal 1190 (amp_factor), though the disclosure is not so limited. Signal 1445 (C) may be the same as signal 845 (C) and/or signal 1150 (phase_factor), though the disclosure is not so limited.

Virtual channel circuitry 1430 may also comprise correction circuitry 1447. Correction circuitry 1447 may comprise virtual channel generator 850 of system 800 of FIG. 8 and/or system 1300 of FIG. 13, though the disclosure is not so limited. As shown in FIG. 14, correction circuitry 1447 may receive signal 1443 (B) and signal 1445 (C), and may output a signal 1450 (illustrated in FIG. 14 as Y′). Signal 1450 may be the same as signal 855 (Y_{corrected}) and/or signal 1319 (y_corrected). That is, signal 1450 may be the generated virtual channel signal that is offset-corrected, amplitude-adjusted, and orthogonal from one of the measured magnetic field channel signals.

Digital controller 1420 may also comprise clock generator circuitry 1422. Clock generator circuitry 1422 may generate a clock signal, which may be used, for example, to advance unit delay circuits, sample and hold circuits, counter circuits, and/or other circuitry in digital controller 1405 or elsewhere in sensor device 1405.

Digital controller 1420 may also comprise pulse generator circuitry 1460. Pulse generator circuitry 1460 may be configured to determine the angle signal based on one of the measured magnetic field channel signals (e.g., X) and the virtual channel signal (e.g., Y′). For example, pulse generator circuitry 1460 may be configured to determine the angle signal according to Equation 1. As previously discussed, the angle signal may be determined by, for example, determining the arctangent of the values of the measured magnetic field channel signal and the virtual channel signal, such as by using the two-argument arctangent function a tan 2. Alternatively, pulse generator circuitry 1460 may determine the angle signal by using a lookup table, a polynomial fit, or a CORDIC calculation, as previously discussed.

Once the value of the angle signal has been determined, the value may be compared with one or more preset threshold values in pulse generator circuitry to determine whether an output event should be generated, as previously discussed. Each time a threshold value is crossed by the value of the angle signal, an output event may be triggered and may be represented, for example, in signal 1464.

Digital controller 1420 may also comprise pulse output stage circuitry 1466. Pulse output stage circuitry 1466 may be configured to generate a series of pulses (see, e.g., FIG. 4A) based on an output event represented in signal 1464. For example, as previously discussed with respect to FIG. 4A, the series of pulses may be generated to have a speed pulse and a number of additional pulses (e.g., up to 9 additional pulses in FIG. 4A) conveying information about the target 245 as part of the output event. In some embodiments, pulse output stage circuitry 1466 may include speed monitor circuitry 1468 for determining a speed of rotation of the target (e.g., target 245) based on the frequency of the output events. Pulse output stage circuitry may output information about the generated pulses as signal 1470.

Digital controller 1420 may also comprise output circuitry 1474. Output circuitry 1474 may comprise output interface circuitry 155 of FIG. 1, for example, though the disclosure is not so limited. Output interface may be configured as any of the types of output circuitry described with respect to output interface circuitry 155 of FIG. 1. For example, FIG. 14 illustrates output circuitry 1474 as generating AK protocol or pulse width modulated (PW) output signals based on the pulses generated by pulse output stage circuitry 1466. The signals may be output as signals 1476 over a conductive interface or wireless interface to another system, such as an ECU of an automobile or a computing system (e.g., computing system 1730), for determining information about the target, such as a speed of rotation, direction of rotation, and/or angle of rotation of the target.

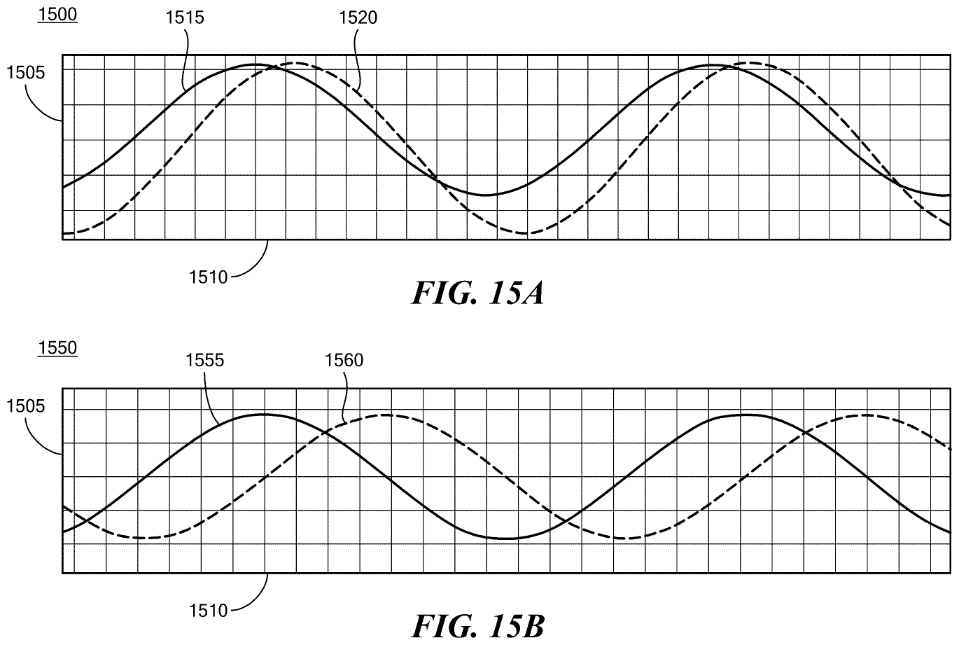

FIG. 15A shows a graph 1500 of example simulated values of measured magnetic field channel signals of a sensor device sensing a magnetic field of a target. Graph 1500 includes a Y-axis 1505 corresponding to amplitude of a measured magnetic field channel signal (e.g., in Volts), and an X-axis 1510 corresponding to an angle of rotation of the simulated target. Channel signal 1515 represents one of the measured magnetic field channel signals and channel signal 1520 represents the other of the measured magnetic field channel signals. As shown in graph 1500, channel signal 1515 and channel signal 1520 may have different offsets, different amplitudes, and may not be orthogonal to one another.

FIG. 15B shows a graph 1550 of example simulated values of measured magnetic field channel signal of a sensor device sensing a magnetic field of a target and of a virtual channel signal of the sensor device. Graph 1500 includes a Y-axis 1505 corresponding to amplitude of a channel signal (e.g., in Volts), and an X-axis 1510 corresponding to an angle of rotation of the simulated target. For example, channel signal 1555 may correspond to the measured magnetic field channel signal and channel signal 1560 may correspond to the virtual channel signal. Virtual channel signal may be generated, for example, using the techniques described herein. As shown in graph 1550, channel signal 1555 and channel signal 1560 may have the same offset, same amplitude, and may be orthogonal to one another.

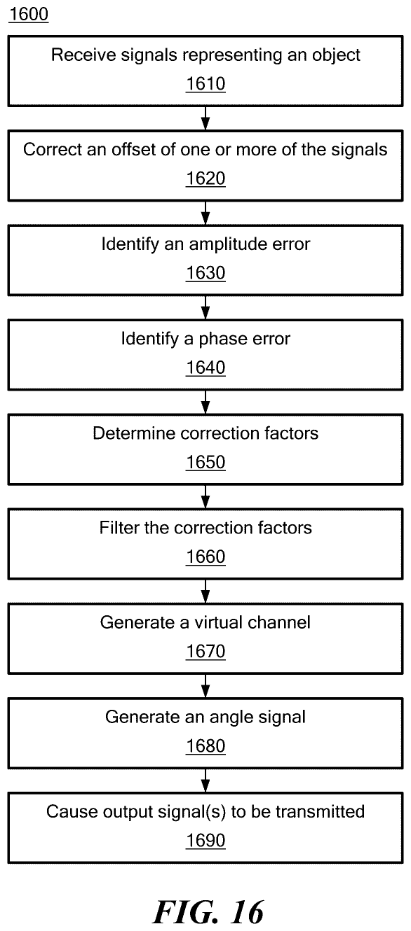

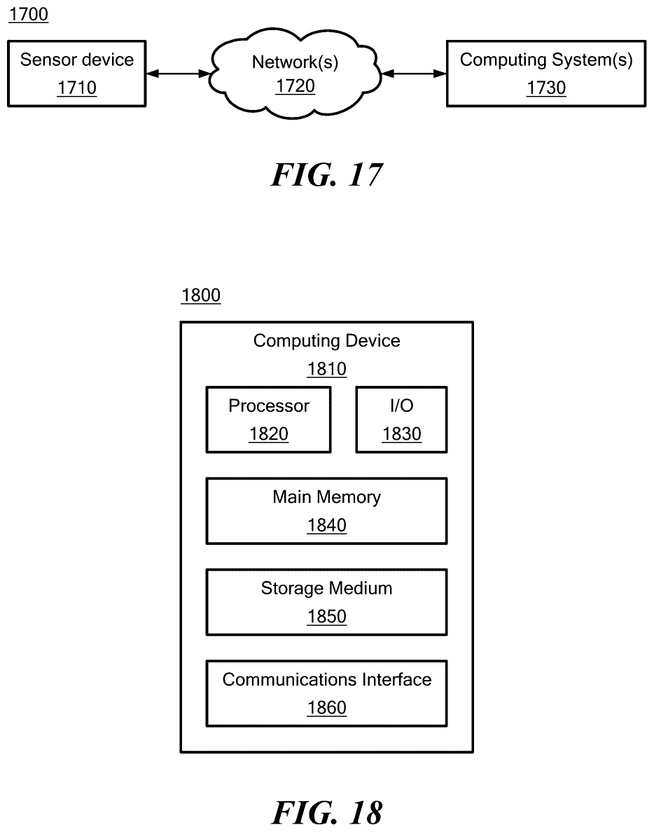

FIG. 16 shows a flow diagram of an example process 1600 for identifying an amplitude error and a phase error between two channel signals of a sensor device, determining correction factors, filtering the correction factors, generating a virtual channel based on the correction factors, generating an angle signal, and causing an output signal to be transmitted. Example process 1600 may be implemented by a sensor device (e.g., sensor device 105, sensor device 205, sensor device 1405). For example, in some embodiments, process 1600 may be implemented by a digital controller (e.g., digital controller 120, digital controller 1420) of a sensor device. In some embodiments, process 1600 may be implemented by one or more computing systems (e.g., computing system(s) 1730 of FIG. 17).

Using process 1600, sensor device(s), controller(s), and/or computing system(s) may automatically correct for errors, such as orthogonality errors between channels caused by mechanical and/or electrical non-idealities in a system. Using process 1600, sensor device(s), controller(s), and/or computing system(s) may also correct for offset and/or amplitude mismatch errors between channels, such as offset and/or amplitude mismatch errors between channels caused by mechanical and/or electrical non-idealities in a system.

In 1610, signals may be received representing an object. For example, a sensor device (e.g., sensor device 105, sensor device 205, sensor device 1405), a controller (e.g., digital controller 120, digital controller 1420), and/or a computing system (e.g., computing system 1730 of FIG. 17) may receive signals representing the magnetic field of a target (e.g., target 101, target 245). The signals may be, for example, signals from one or more magnetic field sensing elements, or channel signals (e.g., signals 109A and 109B, signals 803 (X) and 805 (Y), signals 1426 (Y) and 1427 (X)) generated based on signals from one or more magnetic field sensing elements, as previously discussed.

In 1620, an offset of one or more of the signals may be corrected. For example, as previously discussed, a peak detector and offset detector and corrector (e.g., peak detector and offset detector and corrector 810, peak detection and offset detection and correction circuit 1454) may identify peaks and offsets of the signals (e.g., channel signals) that are received, and may correct the offset (or point around which the sinusoidal signals oscillate) of one or both of these channel signals and/or of a generated virtual channel. The offset detection and correction may be performed with circuitry (as previously discussed) or by a processor (e.g., in a computing system 1730) that, when executing instructions stored in memory, is configured to perform the offset detection and correction.

In 1630, an amplitude error may be identified. For example, as previously discussed, an amplitude and phase error extractor (e.g., amplitude and phase error extractor 820, system 900, phase and amplitude error extraction and correction factor calculation circuit 1219, amplitude and phase error extraction circuit 1429) may determine an amplitude error between the signals (e.g., channel signals) that are received. The amplitude error may be determined with circuitry (as previously discussed) or by a processor (e.g., in a computing system 1730) that, when executing instructions stored in memory, is configured to identify the amplitude error.

In 1640, a phase error may be identified. For example, as previously discussed, an amplitude and phase error extractor (e.g., amplitude and phase error extractor 820, system 900, phase and amplitude error extraction and correction factor calculation circuit 1219, amplitude and phase error extraction circuit 1429) may determine a phase error between the signals (e.g., channel signals) that are received. The phase error may be determined with circuitry (as previously discussed) or by a processor (e.g., in a computing system 1730) that, when executing instructions stored in memory, is configured to identify the phase error.

In 1650, correction factors may be determined. For example, as previously discussed, a correction factor calculator (e.g., correction factor calculator 830, system 1000, phase and amplitude error extraction and correction factor calculation circuit 1219, coefficient calculation circuit 1435) may determine correction factors (e.g., B and C of Equations 10, 16, and 17) based on the identified amplitude and phase errors. The correction factors may be determined with circuitry (as previously discussed) or by a processor (e.g., in a computing system 1730) that, when executing instructions stored in memory, is configured to determine the correction factors.

In 1660, the determined correction factors may be filtered. For example, as previously discussed, a filter (e.g., filter 840, system 1100, filter circuit 1241, filter circuit 1441) may filter the determined correction factors. The correction factors may be filtered with circuitry (as previously discussed) or by a processor (e.g., in a computing system 1730) that, when executing instructions stored in memory, is configured to filter the correction factors.

In 1670, a virtual channel signal may be generated. For example, as previously discussed, a virtual channel generator (e.g., virtual channel generator 850, system 1300, correction circuitry 1447) may generate a virtual channel signal (e.g., Y′, Y_{corrected}, Y_{corrected} of Equation 10) based on the correction factors (e.g., correction factors from 1650 or filtered correction factors from 1660). The virtual channel signal may be generated with circuitry (as previously discussed) or by a processor (e.g., in a computing system 1730) that, when executing instructions stored in memory, is configured to generate the virtual channel signal.

In 1680, an angle signal may be generated. For example, as previously discussed, an angle signal may be generated in a digital controller (e.g., digital controller 120, digital controller 1420), such as in a pulse generator circuit 1460. As previously discussed, the angle signal may be generated, for example, by taking an inverse tangent (i.e., arctangent) of a value of one of the measured channel signals divided by a value of the virtual channel (e.g., such as in accordance with Equation 1). As previously discussed, the two-argument arctangent function a tan 2, commonly used in computing and mathematics, may be used to determine a rotation angle of the target based on values (e.g., voltages) of the measured channel signal and of the virtual channel signal at a given time. As also previously discussed, various other techniques may be used to determine a rotation angle of the target instead of using an inverse tangent function, such as by using a lookup table, a polynomial fit, or a CORDIC calculation. The angle signal may be generated with circuitry (e.g., in a digital controller 120, 1420) or by a processor (e.g., in a computing system 1730) that, when executing instructions stored in memory, is configured to generate the angle signal.

In 1690, one or more output signals may be caused to be transmitted. For example, as previously discussed, one or more signals representing information (e.g., rotation speed, rotation direction, vibration, rotation angle) of a target may be caused to be output from an output interface (e.g., output interface 155, output circuitry 1474), such as in accordance with an AK protocol (see, e.g., FIGS. 4A, 4B, 14) and/or in accordance with a PWM protocol. In some embodiments, a controller (e.g., digital controller 120, digital controller 1420) in a sensor device may cause the output signal(s) to be transmitted by sending instructions to an output interface or output circuitry. In some embodiments, the one or more output signals may be output from a sensor device over a conductive or wireless interface to another system (e.g., ECU, computing system 1730). In some embodiments, the one or more output signals may be caused to be output by a processor (e.g., in a computing system 1730) that, when executing instructions stored in memory, is configured to cause the output signal(s) to be transmitted. In some embodiments, the output signals may be output for display to a user, or for storage in a memory (e.g., a memory of a computing system 1730, computing device 1810).

Process 1600 may be performed continuously and in real-time, or periodically, such that a sensor device, controller, or computing system implementing process 1600 may correct for offset, amplitude, and/or orthogonality errors over time as the sensor device operates.

Although process 1600 shows 1610 through 1690 as occurring in a particular order, the disclosure is not so limited. For example, as previously discussed and shown in FIG. 9, amplitude and phase errors of the received channel signals may be determined in parallel (e.g., at the same time), rather than one after the other as shown in FIG. 16. Moreover, a person of ordinary skill in the art would recognize that 1640 may occur before 1630 rather than after 1630. Generally, a person of ordinary skill in the art would recognize that the order in which 1610 through 1690 as shown are occurring in FIG. 16 may be varied without departing from the spirit of the disclosure herein, and such variation should be considered to be within the scope of the disclosure herein.

Additionally, a person of ordinary skill in the art would recognize that certain of 1610 through 1690 may occur within a sensor device or within particular components of a sensor device, while others of 1610 through 1690 may occur in a different system (e.g., computing system 1730, computing device 1810) or component. For example, in some embodiments, certain of 1610 through 1690 may be performed by analog and/or digital circuits in a sensor device, while more processing-intensive of 1610 through 1690 may be performed by a different system (e.g., computing system 1730) receiving one or more signals from a sensor device. Alternatively, all of 1610 through 1690 may occur within a sensor device, or all of 1610 through 1690 may occur in a system (e.g., computing system 1730) separate from a sensor device.

FIG. 17 is a block diagram of an example computing environment for implementing embodiments of the present disclosure, in accordance with some embodiments. For example, rather than performing some or all of process 1600 within a sensor device, all or part of process 1600 may be implemented in one or more computing system(s) 1730 connected to a sensor device 1710 over one or more networks 1720. For example, one or more computing systems 1730 may receive one or more signals, data, or other communications from sensor device 1710, and may then perform more computation intensive tasks of process 1600. For example, computing system(s) 1730 may receive measured channel signals from a sensor device, and may generate a virtual channel signal, calculate an angle signal based on one of the measured channel signals and the virtual channel signal, and determine information (e.g., rotation speed, direction, vibration, rotation angle) about a target based on the angle signal. The arrangement and number of components in computing environment 1700 is provided for purposes of illustration. Additional arrangements, numbers of components, and other modifications may be made, consistent with the present disclosure.

As shown in FIG. 17, the computing environment may include a sensor device 1710. Sensor device 1710 may, for example, by a sensor device as previously described (e.g., sensor device 105 of FIG. 1, sensor device 205 of FIG. 2, sensor device 1405 of FIG. 14). Sensor device 1710 may be coupled to one or more computing systems 1730 over one or more networks 1720. Sensor device 1710 may communicate signals, such as signals received from and/or derived from one or more magnetic field sensing elements (e.g., magnetic field sensing elements 102A, 102B of FIG. 1, magnetic field sensing elements 1402 of FIG. 14) to a computing system 1730 over the one or more networks 1720. The signals may, for example, be voltage signals received from the magnetic field sensing elements, measured rotation angles of a target by a sensor device, AK protocol or PWM signals representing rotation speed, rotation direction, vibration, and/or rotation angle information, or any other information generated by a sensor device.

Network(s) 1720 may include, for example, one or more wired and/or wireless networks. By way of example, the network(s) 1720 may include a conductor over which current or voltage signals may be transmitted, an Inter-Integrated Circuit (I₂C) network, a Controller Area Network (CAN) network, a WiFi network, an Ethernet network, a Universal Serial Bus (USB) network, a local area network (LAN) network, a cellular (e.g., 5G) network, and/or any other suitable type of network. Network(s) may be wired, wireless, or a combination of wired and wireless interfaces. In some embodiments, network(s) may be one or more conductors over which sensor device 1710 sends analog and/or digital pulses representing information about the rotating target.

Computing system(s) 1730 may include one or more computing devices (see, e.g., computing device 1810 of FIG. 18). A computing device may be, for example, a computing device that may be used to perform some or all of process 1600 of FIG. 16. For example, rather than having to include a controller or processor with significant processing ability (and perhaps large size and/or high cost) in a sensor device, a less sophisticated controller may be included in a sensor device and signals sent to another computing device such that the other computing device may perform the more complicated and processor-intensive tasks. A computing device 1810 may be, for example, an integrated circuit connected to a sensor device. Alternatively, a computing device 1810 may be a computer, such as a laptop computer, mobile phone, tablet, personal computer, server computer, or other type of computer.

FIG. 18 is a block diagram 1800 of an example computing device 1810, consistent with embodiments of the present disclosure. Computing device 1810 may, for example, perform part of all of process 1600 of FIG. 16 based on signals received over one or more networks (e.g., network(s) 1720) from a sensor device (e.g., sensor device 1710). As shown in FIG. 18, a computing device 1810 may include one or more processors or controllers 1820 for executing instructions. Processors or controllers suitable for the execution of instructions may include, by way of example, both general and special purpose (e.g., application specific integrated circuit (ASIC)) processors or controllers. A computing device 1810 may also include one or more input/output (I/O) devices 1830. By way of example, I/O devices 1830 may include keys, buttons, mice, joysticks, styluses, etc. Keys and/or buttons may be physical and/or virtual (e.g., provided on a touch screen interface). A computing device 1810 may be connected to one or more displays (not shown) via I/O 1830. A display may be implemented using one or more display panels, which may include, for example, one or more cathode ray tube (CRT) displays, liquid crystal displays (LCDs), plasma displays, light emitting diode (LED) displays, touch screen type displays, organic light emitting diode (OLED) displays, or any other type of suitable display.

A computing device 1810 may include one or more storage devices configured to store data and/or software instructions used by processor(s) or controller(s) 1820 to perform operations consistent with disclosed embodiments. For example, computing device 1810 may include main memory 1840 configured to store one or more software programs that, when executed by processor(s) or controller(s) 1820, cause processor(s) or controller(s) 1820 to perform functions or operations consistent with disclosed embodiments.

By way of example, main memory 1840 may include NOR and/or NAND flash memory devices, read only memory (ROM) devices, random access memory (RAM) devices, etc. A computing device 1810 may also include one or more storage mediums 1850. By way of example, storage medium(s) 1850 may include hard drives, solid state drives, etc. A computing device 1810 may include any number of main memories 1840 and storage mediums 1850. A main memory 1840 or storage medium 1850 may, in some embodiments, be a non-transitory computer-readable medium.

A computing device 1810 may further include one or more communication interfaces 1860. Communication interface(s) 1860 may allow one or more signals to be received from a sensor device (e.g., sensor device 1710) over one or more networks 1720, and may allow one or more signals to be transmitted to the sensor device. Example communication interface(s) 1860 include a modem, network interface card (e.g., Ethernet card), communications port, antenna, conductor over which current or voltage signals may be transmitted, an Inter-Integrated Circuit (I₂C) interface, a Controller Area Network (CAN) network interface, a WiFi interface, an Ethernet a Universal Serial Bus (USB) interface, a local area network (LAN) network interface, a cellular (e.g., 5G) interface, and/or any other suitable type of interface for transmitting and/or receiving signals or other information. Communication interface(s) 1860 may transmit software, data, or information in the form of signals, which may be electronic, electromagnetic, optical, and/or other types of signals. The signals may be provided to/from communications interface 1860 via a communications path (e.g., network(s) 1720), which may be implemented using wired, wireless, cable, fiber optic, radio frequency (RF), and/or other communications channels.

As used herein, the term “processor” or “controller” is used to describe electronic circuitry that performs a function, an operation, or a sequence of operations. The function, operation, or sequence of operations can be hard coded into the electronic circuit or soft coded by way of instructions held in a memory device. The function, operation, or sequence of operations can be performed using digital values or using analog signals. In some embodiments, the processor or controller can be embodied in an application specific integrated circuit (ASIC), which can be an analog ASIC or a digital ASIC, in a microprocessor with associated program memory and/or in a discrete electronic circuit, which can be analog or digital. A processor or controller can contain internal processors or modules that perform portions of the function, operation, or sequence of operations. Similarly, a module can contain internal processors or internal modules that perform portions of the function, operation, or sequence of operations of the module.

While electronic circuits shown in figures herein may be shown in the form of analog blocks or digital blocks, it will be understood that the analog blocks can be replaced by digital blocks that perform the same or similar functions and the digital blocks can be replaced by analog blocks that perform the same or similar functions. Analog-to-digital or digital-to-analog conversions may not be explicitly shown in the figures but should be understood.

Various embodiments of the systems, methods, and techniques are described herein with reference to the related drawings. Alternative embodiments can be devised without departing from the scope of the described concepts. It is noted that various connections and positional relationships (e.g., over, below, adjacent, etc.) are set forth between elements in the following description and in the drawings. These connections and/or positional relationships, unless specified otherwise, can be direct or indirect, and the present invention is not intended to be limiting in this respect. Accordingly, a coupling of entities can refer to either a direct or an indirect coupling, and a positional relationship between entities can be a direct or indirect positional relationship. As an example of an indirect positional relationship, references in the present description to element or structure A over element or structure B include situations in which one or more intermediate elements or structures (e.g., element C) is between elements A and B regardless of whether the characteristics and functionalities of elements A and/or B are substantially changed by the intermediate element(s).

Furthermore, it should be appreciated that relative, directional or reference terms (e.g. such as “above,” “below,” “left,” “right,” “top,” “bottom,” “vertical,” “horizontal,” “front,” “back,” “rearward,” “forward,” etc.) and derivatives thereof are used only to promote clarity in the description of the figures. Such terms are not intended as, and should not be construed as, limiting. Such terms may simply be used to facilitate discussion of the drawings and may be used, where applicable, to promote clarity of description when dealing with relative relationships, particularly with respect to the illustrated embodiments. Such terms are not, however, intended to imply absolute relationships, positions, and/or orientations. For example, with respect to an object or structure, an “upper” or “top” surface can become a “lower” or “bottom” surface simply by turning the object over. Nevertheless, it is still the same surface and the object remains the same. Also, as used herein, “and/or” means “and” or “or,” as well as “and” and “or.” Moreover, all patent and non-patent literature cited herein is hereby incorporated by references in their entirety.

The terms “disposed over,” “overlying,” “atop,” “on top,” “positioned on” or “positioned atop” mean that a first element, such as a first structure, is present on a second element, such as a second structure, where intervening elements or structures (such as an interface structure) may or may not be present between the first element and the second element. The term “direct contact” means that a first element, such as a first structure, and a second element, such as a second structure, are connected without any intermediary elements or structures between the interface of the two elements. The term “connection” can include an indirect connection and a direct connection.

In the foregoing detailed description, various features are grouped together in one or more individual embodiments for the purpose of streamlining the disclosure. This method of disclosure is not to be interpreted as reflecting an intention that each claim requires more features than are expressly recited therein. Rather, inventive aspects may lie in less than all features of each disclosed embodiment.

References in the disclosure to “one embodiment,” “an embodiment,” “some embodiments,” or variants of such phrases indicate that the embodiment(s) described can include a particular feature, structure, or characteristic, but every embodiment can include the particular feature, structure, or characteristic. Moreover, such phrases are not necessarily referring to the same embodiment(s). Further, when a particular feature, structure, or characteristic is described with reference to one embodiment, knowledge of one skilled in the art may be relied upon to affect such feature, structure, or characteristic in connection with other embodiments whether or not explicitly described.

The disclosed subject matter is not limited in its application to the details of construction and to the arrangements of the components set forth in the following description or illustrated in the drawings. The disclosed subject matter is capable of other embodiments and of being practiced and carried out in various ways. As such, those skilled in the art will appreciate that the conception, upon which this disclosure is based, may readily be utilized as a basis for the designing of other structures, methods, and systems for carrying out the several purposes of the disclosed subject matter. Therefore, the claims should be regarded as including such equivalent constructions insofar as they do not depart from the spirit and scope of the disclosed subject matter.

Although the disclosed subject matter has been described and illustrated in the foregoing exemplary embodiments, it is understood that the present disclosure has been made only by way of example, and that numerous changes in the details of implementation of the disclosed subject matter may be made without departing from the spirit and scope of the disclosed subject matter.

All publications and references cited herein are expressly incorporated herein by reference in their entirety.

1. A sensor device, comprising:
magnetic field sensing elements, each of the magnetic field sensing elements arranged to sense a magnetic field associated with a rotating target; and
circuitry configured to:
receive a first channel signal representative of the magnetic field as sensed by a first one or more of the magnetic field sensing elements;
receive a second channel signal representative of the magnetic field as sensed by a second one or more of the magnetic field sensing elements;
identify an amplitude error and a phase error between the first channel signal and the second channel signal;
determine a first correction factor based at least in part on the identified amplitude error and a second correction factor based at least in part on the identified phase error;
generate a virtual channel signal based at least in part on the first correction factor and the second correction factor; and
generate an angle signal based on the generated virtual channel signal and one of the first channel signal or the second channel signal.

2. The sensor device of claim 1, wherein the generated virtual channel signal differs in phase from the first channel signal or the second channel signal by ninety degrees.

3. The sensor device of claim 1, wherein the circuitry is further configured to correct for an offset of at least one of the first channel signal or the second channel signal.

4. The sensor device of claim 1, wherein the generated virtual channel signal is equal in amplitude to an amplitude of the first channel signal or an amplitude of the second channel signal.

5. The sensor device of claim 1, further comprising a memory storing instructions, wherein the circuitry comprises a digital controller that, when executing the instructions, is configured to identify the amplitude error and the phase error, determine the first correction factor and the second correction factor, generate the virtual channel signal, and generate the angle signal.

6. The sensor device of claim 1, wherein the circuitry further comprises:
a phase error extraction circuit for extracting the phase error between the first channel signal and the second channel signal; and
an amplitude error extraction circuit for extracting the amplitude error between the first channel signal and the second channel signal.

7. The sensor device of claim 6, wherein the phase error extraction circuit is configured to:
count a first time between a peak of the first channel signal and a peak of the second channel signal;
count a second time between two peaks of the first channel signal or the second channel signal; and
determine the phase error based on the first time and the second time.

8. The sensor device of claim 1, wherein the first correction factor is determined according to the formula
$$B = \frac{1}{A * cos ( φ )}$$
where B is the first correction factor, A is the amplitude error between the first channel signal and the second channel signal, and φ is the phase error between the first channel signal and the second channel signal.

9. The sensor device of claim 1, wherein the second correction factor is determined according to the formula
C=−tan(φ)
where C is the second correction factor and φ is the phase error between the first channel signal and the second channel signal.

10. The sensor device of claim 1, wherein the first correction factor and the second correction factor are calculated using Pade's approximation.

11. The sensor device of claim 1, wherein:
the first correction factor B is determined according to the formula
$$B = \frac{1}{A * cos ( φ )}$$
where A is the amplitude error between the first channel signal and the second channel signal, and φ is the phase error between the first channel signal and the second channel signal;
the second correction factor C is determined according to the formula
C=−tan(φ); and
the virtual channel signal is determined according to the formula
Y_{corrected}=B*Y+C*Y
where Y_{corrected} is the virtual channel signal and Y is one of the first channel signal or the second channel signal.

12. The sensor device of claim 1, wherein the circuitry is further configured to:
filter the first correction factor and the second correction factor; and
generate the virtual channel signal based at least in part on the filtered first correction factor and the filtered second correction factor.

13. The sensor device of claim 1, wherein the circuitry is further configured to cause output signals to be transmitted, the output signals representing at least one of a speed of rotation of the rotating target or an angle of rotation of the rotating target.

14. The sensor device of claim 1, wherein the magnetic field sensing elements comprise one of giant magnetoresistance (GMR) elements, Hall plate elements, or tunneling magnetoresistance (TMR) elements.

15. The sensor device of claim 1, wherein the circuitry comprises a filtering circuit, the filtering circuit comprising:
a dynamic scaling factor circuit for scaling a bandwidth of the filtering circuit during operation of the sensor device; and
a low pass filter circuit that filters the first correction factor and the second correction factor based at least in part on the scaled bandwidth and on a previously filtered first correction and second correction factor.

16. A method, comprising:
receiving a first channel signal representative of a magnetic field as sensed by one or more first magnetic field sensing elements, the magnetic field associated with a rotating target;
receiving a second channel signal representative of the magnetic field as sensed by one or more second magnetic field sensing elements;
identifying an amplitude error and a phase error between the first channel signal and the second channel signal;
determining a first correction factor based at least in part on the identified amplitude error and a second correction factor based at least in part on the identified phase error;
generating a virtual channel signal based at least in part on the first correction factor and the second correction factor; and
generating an angle signal based on the generated virtual channel signal and one of the first channel signal or the second channel signal.

17. The method of claim 16, wherein the generated virtual channel signal differs in phase from the first channel signal or the second channel signal by ninety degrees and is equal in amplitude to an amplitude of the first channel signal or an amplitude of the second channel signal.

18. The method of claim 16, wherein the first channel signal and the second channel signal are arranged to be orthogonal to each other, and wherein the first correction factor and the second correction factor are used to generate the virtual channel signal orthogonal to one of the first channel signal or the second channel signal to correct for orthogonality errors, the orthogonality errors caused by at least one of a mechanical or electrical non-ideality.

19. The method of claim 16, further comprising transmitting at least one of output event signals when the angle signal crosses predetermined threshold values or signals representing rotation angles.

20. The method of claim 16, wherein the first correction factor is determined according to the formula
$$B = \frac{1}{A * cos ( φ )}$$
where B is the first correction factor, A is the amplitude error between the first channel signal and the second channel signal, and φ is the phase error between the first channel signal and the second channel signal, where the amplitude error is a ratio between an amplitude of the first channel signal and an amplitude of the second channel signal.

21. The method of claim 16, wherein the second correction factor is determined according to the formula
C=−tan(φ)
where C is the second correction factor and φ is the phase error between the first channel signal and the second channel signal.

22. The method of claim 16, wherein:
the first correction factor B is determined according to the formula
$$B = \frac{1}{A * cos ( φ )}$$
where A is the amplitude error between the first channel signal and the second channel signal, and φ is the phase error between the first channel signal and the second channel signal;
the second correction factor C is determined according to the formula
C=−tan(φ); and
the virtual channel signal is determined according to the formula
Y_{corrected}=B*Y+C*Y
where Y_{corrected} is the virtual channel signal and Y is one of the first channel signal or the second channel signal.

23. The method of claim 16, further comprising:
filtering the first correction factor and the second correction factor; and
generating the virtual channel signal based at least in part on the filtered first correction factor and the filtered second correction factor.
